(19) United States
(12) Patent Application Publication
(10) Pub. No.: US 2026/0267322 A1
(43) Pub. Date: Sep. 10, 2026

(54) ESTIMATION ALGORITHM GENERATION DEVICE, INFORMATION PROCESSING APPARATUS, ESTIMATION ALGORITHM GENERATION METHOD AND PROCESSING CONDITION DETERMINATION METHOD

(71) Applicant: SCREEN HOLDINGS CO., LTD., Kyoto (JP)

(72) Inventors: Keitaro FUKUDA, Kyoto-shi, Kyoto (JP); Kensuke SHINOHARA, Kyoto-shi, Kyoto (JP); Yoshinori TAKAGI, Kyoto-shi, Kyoto (JP)

(21) Appl. No.: 19/166,145

(22) PCT Filed: Dec. 28, 2023
(86) PCT No.: PCT/JP2023/047248

§ 371 Date: Sep. 17, 2025

(30) Foreign Application Priority Data
Mar. 24, 2023 (JP) 2023-048663

(51) Int. Cl. G05B 19/418

(52) U.S. Cl. CPC G05B 19/41885; G05B 2219/34122; G05B 2219/45031

(57) ABSTRACT

An estimation algorithm generation device includes a hardware processor, wherein the hardware processor acquires a plurality of first datasets, and determines a first parameter by providing the plurality of first datasets to a predetermined first function to perform a regression analysis, the first dataset includes a first processing result and a first processing condition, with the first processing result being obtained after a substrate processing apparatus executes a film process according to the first processing condition, the first processing result includes a difference between film thicknesses obtained before and after execution of the film process at each of a plurality of different positions in a radial direction of the substrate, and the first function expresses, using the first processing condition and the first parameter, a difference between film thicknesses obtained before and after execution of the film process at any position in the radial direction of the substrate.

### TECHNICAL FIELD

The present invention relates to an estimation algorithm generation device, an information processing apparatus, an estimation algorithm generation method and a processing condition determination method.

### BACKGROUND ART

In a semiconductor manufacturing process, there is a cleaning process. In the cleaning process, the thickness of a film formed on a substrate is adjusted by an etching process of applying a chemical liquid to the substrate. In this film-thickness adjustment, it is important to execute the etching process such that the surface of the substrate is uniform. It is also important to adjust the film thickness so as to obtain a desired film-thickness distribution by increasing an etching amount near the edge of the substrate, etc. In a case in which an etching liquid is discharged from a nozzle to a portion of the substrate, the nozzle is required to be moved in a radial direction with respect to the substrate. However, the etching process is a complicated process in which a processing amount indicating how much a film is to be processed changes due to differences in work of moving a nozzle. Further, the processing amount indicating how much the film is to be processed in the etching process is provided after the substrate is processed. Therefore, trial and error by an engineer are required to set the work for moving the nozzle. Determination for optimal nozzle work is costly and time consuming.

Patent Document 1 describes a device that determines scan speed information based on a target processing amount by using a trained model that has executed machine learning using training data in which “input” is a processing amount (etching amount) and “output” is the scan speed information. With this technique, one scan speed information piece is determined based on the target processing amount.
[Patent Document 1] JP 2021-108367 A

### SUMMARY OF INVENTION

### Technical Problem

On the other hand, in regard to etching for a film formed on a substrate, it is known that a temperature of a processing liquid, a rotation speed of the substrate, a flow rate of the processing liquid, and the like influence an etching processing amount. Since the trained model described in Patent Document 1 does not take a temperature of a processing liquid, a rotation speed of a substrate, a flow rate of the processing liquid, and the like into account, it is not possible to handle a case in which different temperatures of a processing liquid, different rotation speeds of the substrate and different flow rates of the processing liquid are used. Further, because a trained model is a black box, different trained models are generated due to differences of the training data to be used in machine learning. Therefore, there is a problem that it is not easy to collect and determine training data suitable for generation of a trained model.

One object of the present invention is to provide an estimation algorithm generation device and an estimation algorithm generation method that enable easy generation of an estimation algorithm adapted for a substrate processing apparatus.

Another object of the present invention is to provide an information processing apparatus and a processing condition determination method that enable presentation of a plurality of processing conditions with respect to a processing result of a complicated process of processing a substrate.

### Solution to Problem

An estimation algorithm generation device according to one aspect of the present invention includes a first data acquirer that acquires a plurality of first datasets, and a first determiner that determines a first parameter by providing the plurality of first datasets to a predetermined first function to perform a regression analysis, wherein each of the plurality of first datasets includes a first processing result and a first processing condition, with the first processing result being obtained after a substrate processing apparatus executes a film process according to the first processing condition by supplying a processing liquid to an upper surface of a substrate on which a film is formed, the first processing result includes a difference between film thicknesses obtained before and after execution of the film process at each of a plurality of different positions in a radial direction of the substrate, and the first function expresses, using the first processing condition and the first parameter, a difference between film thicknesses obtained before and after execution of the film process at any position in the radial direction of the substrate.

An information processing apparatus according to another aspect of the present invention manages a substrate processing apparatus, wherein the substrate processing apparatus executes a film process by supplying a processing liquid to an upper surface of a substrate on which a film is formed, the information processing apparatus includes a processing condition determiner that determines a first processing condition for execution of the film process by the substrate processing apparatus, the estimation algorithm is a first function that calculates, using a first parameter, based on the first processing condition, a difference between film thicknesses obtained before and after the film process at any position in a radial direction of the substrate on which the substrate processing apparatus executes the film process, the first parameter is obtained by providing a plurality of first datasets to the first function to perform a regression analysis, each of the plurality of first datasets includes a first processing result and the first processing condition, with the first processing result being obtained after the substrate processing apparatus is driven according to the first processing condition and executes the film process, the first processing result includes a difference between film thicknesses obtained before and after execution of the film process at each of a plurality of different positions in the radial direction of the substrate, and the processing condition determiner, in a case in which the first processing result that is calculated based on a temporary processing condition using the estimation algorithm satisfies an allowable condition, determines a temporary first processing condition as the first processing condition for driving the substrate processing apparatus.

An estimation algorithm generation method according to another aspect of the present invention includes a step of acquiring a plurality of first datasets, and a step of determining a first parameter by providing the plurality of first datasets to a first function to perform a regression analysis, wherein each of the plurality of first datasets includes a first processing result and a first processing condition, with the first processing result being obtained after a substrate processing apparatus executes a film process according to the first processing condition by supplying a processing liquid to an upper surface of a substrate on which a film is formed, the first processing result includes a difference between film thicknesses obtained before and after execution of the film process at each of a plurality of different positions in a radial direction of the substrate, and the first function that expresses, using the first processing condition and the first parameter, a difference between film thicknesses obtained before and after execution of the film process at any position in the radial direction of the substrate, is predetermined.

A processing condition determination method according to another aspect of the present invention that is executed by an information processing apparatus managing a substrate processing apparatus, wherein the substrate processing apparatus executes a film process by supplying a processing liquid to an upper surface of a substrate on which a film is formed, the processing condition determination method includes a processing condition determination step of determining a first processing condition for execution of the film process by the substrate processing apparatus, the estimation algorithm is a first function for calculating a first processing result based on the first processing condition using a first parameter, the first processing result includes a difference between film thicknesses obtained before and after execution of the film process at each of a plurality of different positions in a radial direction of the substrate, the first parameter is obtained when a plurality of first datasets is provided to the first function and a regression analysis is performed, each of the plurality of first datasets includes the first processing result and the first processing condition, with the first processing result being obtained after the substrate processing apparatus executes the film process according to the first processing condition, and the processing condition determination step includes, in a case in which a first processing result that is calculated based on a temporary first processing condition using the estimation algorithm satisfies an allowable condition, determining the temporary first processing condition as the first processing condition for driving the substrate processing apparatus.

### Advantageous Effects of Invention

With the present invention, it is possible to provide an estimation algorithm generation device and an estimation algorithm generation method that enable easy generation of an estimation algorithm adapted for a substrate processing apparatus.

Further, it is possible to provide an information processing apparatus and a processing condition determination method that enable presentation of a plurality of processing conditions for a processing result of a complicated process of processing a substrate.

### BRIEF DESCRIPTION OF THE DRAWINGS

FIG. 1 is a diagram for explaining the configuration of a substrate processing system according to one embodiment of the present invention.

FIG. 2 is a diagram showing one example of the configuration of an information processing apparatus.

FIG. 3 is a diagram showing one example of the configuration of an estimation algorithm generation device.

FIG. 4 is a diagram showing one example of the functional configuration of the substrate processing system according to the one embodiment.

FIG. 5 is a diagram for explaining a processing result.

FIG. 6 is a diagram showing one example of the functions for generating an estimation algorithm that takes a back-surface discharge process for account among functions of an estimation algorithm generator according to the present embodiment.

FIG. 7 is a diagram showing one example of a first processing result.

FIG. 8 is a diagram showing a first function F1(x).

FIG. 9 is a diagram showing a first influence degree for each of a plurality of different positions in a radial direction of a substrate.

FIG. 10 is a diagram showing one example of a second function F2(x).

FIG. 11 is a diagram for explaining the behavior of an etching liquid with respect to the work of an obverse-surface nozzle of a substrate processing apparatus.

FIG. 12 is a diagram showing, based on variable conditions, coverage rates obtained based on a plurality of second processing results.

FIG. 13 is a diagram showing one example of a third function H(x).

FIG. 14 is a diagram showing one example of the functions for generating an estimation algorithm that does not take the back-surface discharge process into account among the functions of the estimation algorithm generator.

FIG. 15 is a flowchart showing one example of a flow of an estimation algorithm generation process.

FIG. 16 is a flowchart showing one example of a flow of a first function determination process.

FIG. 17 is a flowchart showing one example of a flow of a second function determination process.

FIG. 18 is a flowchart showing one example of a flow of a third function determination process that takes the back-surface discharge process into account.

FIG. 19 is a flowchart showing one example of a flow of a third function determination process that does not take the back-surface discharge process into account.

FIG. 20 is a diagram showing one example of the functions of an estimation algorithm generator.

### DESCRIPTION OF EMBODIMENTS

A substrate processing system according to one embodiment of the present invention will be described below in detail with reference to the drawings. In the following description, a substrate refers to a semiconductor substrate (semiconductor wafer), a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like.

### (1) Overall Configuration of Substrate Processing System

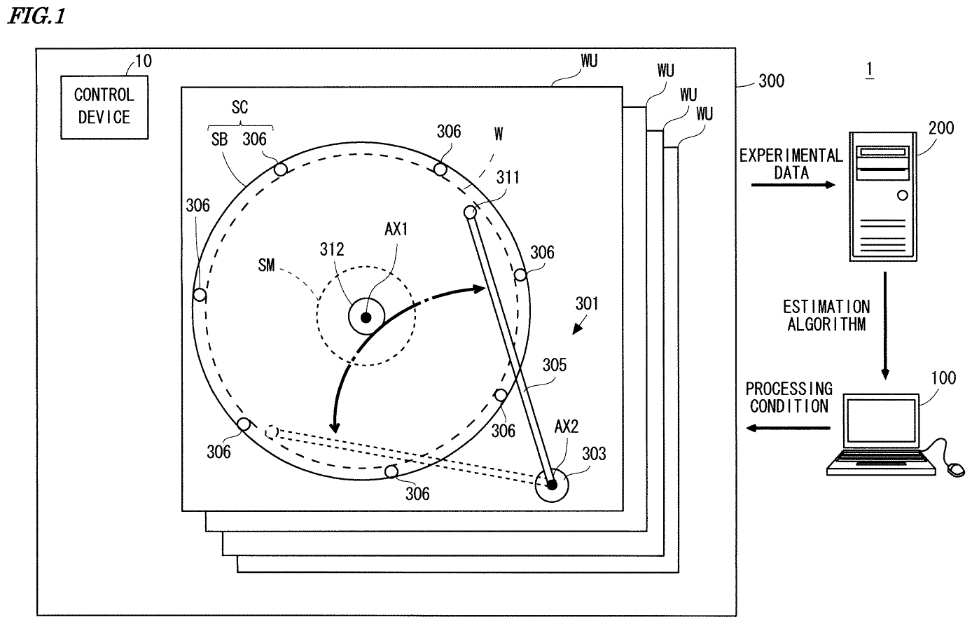

FIG. 1 is a diagram for explaining the configuration of the substrate processing system according to the one embodiment of the present invention. The substrate processing system 1 of FIG. 1 includes an information processing apparatus 100, an estimation algorithm generation device 200 and a substrate processing apparatus 300. The estimation algorithm generation device 200 is a server, for example, and the information processing apparatus 100 is a personal computer, for example.

The estimation algorithm generation device 200 and the information processing apparatus 100 are used to manage the substrate processing apparatus 300. The number of substrate processing apparatuses 300 to be managed by the estimation algorithm generation device 200 and the information processing apparatus 100 is not limited to one, and a plurality of substrate processing apparatuses 300 may be managed by the estimation algorithm generation device 200 and the information processing apparatus 100.

In the substrate processing system 1 according to the present embodiment, the information processing apparatus 100, the estimation algorithm generation device 200 and the substrate processing apparatus 300 are connected to one another by a wired communication line, a wireless communication line or a communication network. The information processing apparatus 100, the estimation algorithm generation device 200 and the substrate processing apparatus 300 are respectively connected to a network and can transmit and receive data to and from one another. As the network, a Local Area Network (LAN) or a Wide Area Network (WAN) is used, for example. Further, the network may be the Internet. Further, the information processing apparatus 100 and the substrate processing apparatus 300 may be connected to each other via a dedicated communication network. The connection state of the network may be wired or wireless.

The estimation algorithm generation device 200 is not necessarily required to be connected to the substrate processing apparatus 300 or the information processing apparatus 100 via a communication line or a communication network. In this case, data generated in the substrate processing apparatus 300 may be transferred to the estimation algorithm generation device 200 via a recording medium. Further, data generated in the estimation algorithm generation device 200 may be transferred to the information processing apparatus 100 via a recording medium.

In the substrate processing apparatus 300, a display device, a speech output device and an operation unit (not shown) are provided. The substrate processing apparatus 300 runs according to a predetermined processing condition (processing recipe).

### (2) Outline of Substrate Processing Apparatus

The substrate processing apparatus 300 includes a control device 10 and a plurality of substrate processing units WU. The control device 10 controls the plurality of substrate processing units WU. Each of the plurality of substrate processing units WU executes a film process on a substrate W by supplying a certain flow rate of a processing liquid to the substrate W on which a film is formed. While the substrate W to be processed has a diameter of 300 mm in the present embodiment, the present invention is not limited to this. The processing liquid includes an etching liquid, and the substrate processing unit WU executes an etching process. The etching liquid is a chemical liquid. The etching liquid is a fluoronitric acid (a liquid mixture of hydrofluoric acid (HF) and nitric acid (HNO₃)), hydrofluoric acid, buffered hydrofluoric acid (BHF), ammonium fluoride, HFEG (a liquid mixture of hydrofluoric acid and ethylene glycol) or phosphoric acid (H₃PO₄), for example.

The substrate processing unit WU includes a spin chuck SC, a spin motor SM, an obverse-surface nozzle 311, a nozzle moving mechanism 301 and a back-surface nozzle 312. The spin chuck SC includes a disc-shaped spin base SB held in a horizontal attitude and a plurality of chuck pins 306 that can hold the substrate W in a horizontal attitude above the spin base SB. Thus, the spin chuck SC horizontally holds the substrate W. The substrate W is held by the spin chuck SC such that a first rotation axis AX1 of the spin motor SM coincides with the center of the substrate W. The spin motor SM has the first rotation axis AX1. The first rotation axis AX1 extends in an upward-and-downward direction. The spin chuck SC is attached to the upper end portion of the first rotation axis AX1 of the spin motor SM. When the spin motor SM rotates, the spin chuck SC rotates about the first rotation axis AX1. The spin motor SM is a stepping motor. The substrate W held by the spin chuck SC rotates about the first rotation axis AX1. Therefore, the rotation speed of the substrate W is equal to the rotation speed of the stepping motor. In a case in which an encoder that generates a rotation-speed signal indicating a rotation speed of the spin motor SM is provided, the rotation speed of the substrate W may be acquired from the rotation-speed signal generated by the encoder. In this case, a motor other than the stepping motor can be used as the spin motor SM.

The obverse-surface nozzle 311 supplies the etching liquid to an obverse surface (upper surface) of the substrate W held by the spin chuck SC. The etching liquid is supplied from an etching liquid supplier (not shown) to the obverse-surface nozzle 311. The obverse-surface nozzle 311 discharges the etching liquid to the obverse surface of the rotating substrate W. A back-surface nozzle 312 supplies the etching liquid to a back surface (lower surface) of the substrate W held by the spin chuck SC. The etching liquid is supplied from an etching liquid supplier (not shown) to the back-surface nozzle 312, and the back-surface nozzle 312 discharges the etching liquid to the back surface of the rotating substrate W. Hereinafter, a process of discharging the etching liquid through the back-surface nozzle 312 is referred to as a back-surface discharge process.

The nozzle moving mechanism 301 moves the obverse-surface nozzle 311 in a substantially horizontal direction. Specifically, the nozzle moving mechanism 301 has a nozzle motor 303 having a second rotation axis AX2 and a nozzle arm 305. The nozzle motor 303 is arranged such that the second rotation axis AX2 extends in a substantially vertical direction. The nozzle arm 305 has a longitudinal shape extending linearly. One end of the nozzle arm 305 is attached to the upper end of the second rotation axis AX2 such that the longitudinal direction of the nozzle arm 305 is different from the direction of the second rotation axis AX2. The obverse-surface nozzle 311 is attached to the other end of the nozzle arm 305 such that an outlet port for the etching liquid is directed downwardly.

When the nozzle motor 303 works, the nozzle arm 305 rotates about the second rotation axis AX2 in a horizontal plane. Thus, the obverse-surface nozzle 311 attached to the other end of the nozzle arm 305 moves (turns) in the horizontal direction about the second rotation axis AX2. The obverse-surface nozzle 311 discharges the etching liquid toward the substrate W while moving in the horizontal direction. The nozzle motor 303 is a stepping motor, for example.

The control device 10 includes a CPU (Central Processing Unit) and a memory, and controls the substrate processing apparatus 300 as a whole by execution by the CPU of a program stored in the memory. The control device 10 controls the spin motor SM and the nozzle motor 303.

The estimation algorithm generation device 200 receives experimental data from the substrate processing apparatus 300. The estimation algorithm generation device 200 generates an estimation algorithm using the experimental data and outputs the estimation algorithm to the information processing apparatus 100. In the present embodiment, the estimation algorithm includes a first function F(x), a second function F2(x) and a third function F3(x), described below.

The information processing apparatus 100 determines a processing condition for processing a substrate to be processed by the substrate processing apparatus 300 using the estimation algorithm. The information processing apparatus 100 outputs the determined processing condition to the substrate processing apparatus 300.

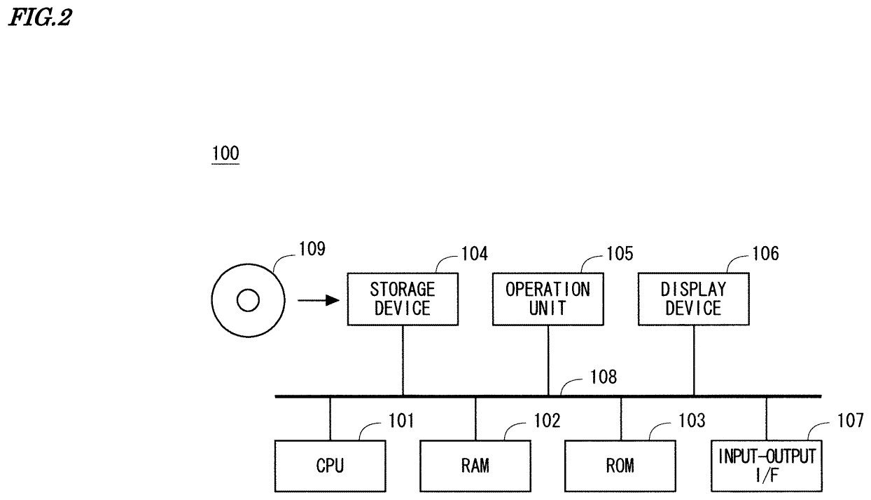

FIG. 2 is a diagram showing one example of the configuration of the information processing apparatus. With reference to FIG. 2, the information processing apparatus 100 includes a CPU 101, a RAM (Random Access Memory) 102, a ROM (Read Only Memory) 103, a storage device 104, an operation unit 105, a display device 106 and an input-output I/F (interface) 107. The CPU 101, the RAM 102, the ROM 103, the storage device 104, the operation unit 105, the display device 106 and the input-output I/F 107 are connected to a bus 108.

The RAM 102 is used as a work area for the CPU 101. A system program is stored in the ROM 103. The storage device 104 includes a storage medium such as a hard disc or a semiconductor memory and stores a program. A program may be stored in the ROM 103 or another external storage device.

A CD-ROM 109 is attachable to and detachable from the storage device 104. A recording medium storing a program to be executed by the CPU 101 is not limited to the CD-ROM 109. It may be an optical disc (MO (Magnetic Optical Disc)/MD (Mini Disc)/DVD (Digital Versatile Disc)), an IC card, an optical card, and a semiconductor memory such as a mask ROM or an EPROM (Erasable Programmable ROM). Further, the CPU 101 may download a program from a computer connected to the network to store the program in the storage device 104. Alternatively, the computer connected to the network may write a program in the storage device 104, and the program stored in the storage device 104 may be loaded into the RAM 102 to be executed in the CPU 101. The program referred to here includes not only a program directly executable by the CPU 101 but also a source program, a compressed program, an encrypted program and the like.

The operation unit 105 is an input device such as a keyboard, a mouse or a touch panel. A user can provide a predetermined instruction to the information processing apparatus 100 by operating the operation unit 105. The display device 106 is a display device such as a liquid crystal display device and displays a GUI (Graphical User Interface) or the like for receiving an instruction from the user. The input-output I/F 107 is connected to the network.

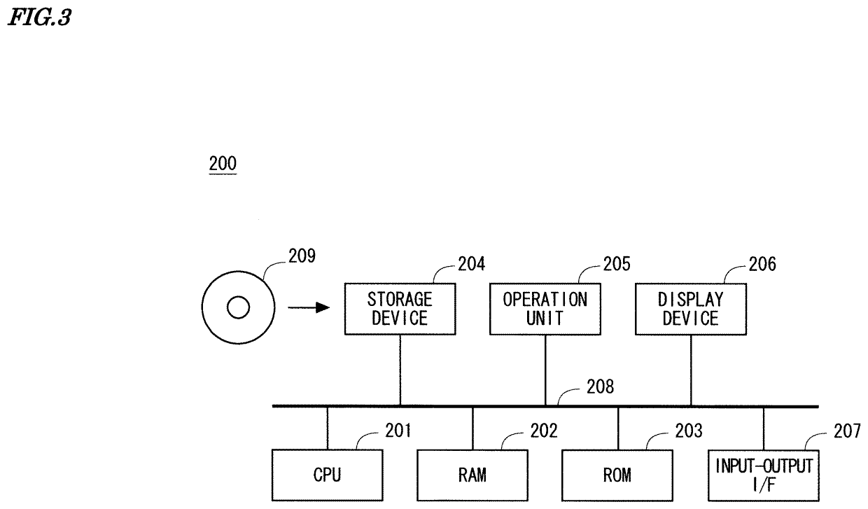

FIG. 3 is a diagram showing one example of the configuration of the estimation algorithm generation device. With reference to FIG. 3, the estimation algorithm generation device 200 includes a CPU 201, a RAM 202, a ROM 203, a storage device 204, an operation unit 205, a display device 206 and an input-output I/F 207. The CPU 201, the RAM 202, the ROM 203, the storage device 204, the operation unit 205, the display device 206 and the input-output I/F 207 are connected to a bus 208.

The RAM 202 is used as a work area for the CPU 201. A system program is stored in the ROM 203. The storage device 204 includes a storage medium such as a hard disc or a semiconductor memory and stores a program. The program may be stored in the ROM 203 or another external storage device. A CD-ROM 209 is attachable to and detachable from the storage device 204.

The operation unit 205 is an input device such as a keyboard, a mouse or a touch panel. The input-output I/F 207 is connected to the network.

### (3) Functional Configuration of Substrate Processing System

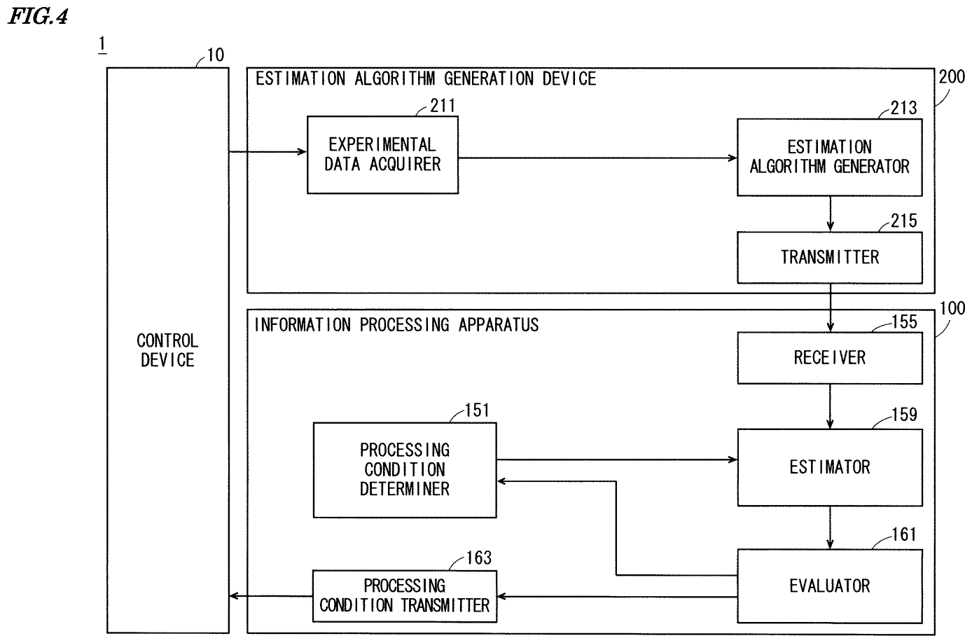

FIG. 4 is a diagram showing one example of the functional configuration of the substrate processing system according to the one embodiment. With reference to FIG. 4, the control device 10 included in the substrate processing apparatus 300 controls the substrate processing unit WU to execute a film process on the substrate W according to a processing condition in a processing period of time. The processing period of time is the period of time defined in regard to the film process for the substrate. In the present embodiment, the processing period of time is the period of time during which the obverse-surface nozzle 311 discharges the etching liquid to the substrate W. The processing condition is a condition used when the substrate processing unit WU executes the film process.

The processing condition includes a temperature of the etching liquid, a concentration of the etching liquid, a flow rate of the etching liquid, a rotation speed of the substrate W and a position of the obverse-surface nozzle 311. A concentration of the etching liquid is indicated by a mixing ratio of a plurality of chemical liquids. A position of the obverse-surface nozzle 311 is indicated by a relative position of the obverse-surface nozzle 311 with respect to the substrate W at each of a plurality of points in time during execution of the film process. A relative position of the obverse-surface nozzle 311 with respect to the substrate W is indicated by a rotation angle of the nozzle motor 303.

A processing condition includes a fixed condition that does not vary over time and a variable condition that varies over time. In the present embodiment, a fixed condition is a temperature of the etching liquid, a concentration of the etching liquid, a flow rate of the etching liquid, a rotation speed of the substrate W, and a variable condition is a relative position of the obverse-surface nozzle 311 with respect to the substrate W, with the relative position varying over time.

The estimation algorithm generation device 200 includes an experimental data acquirer 211, an estimation algorithm generator 213 and a transmitter 215. The functions of the estimation algorithm generation device 200 is implemented by the CPU 201 included in the estimation algorithm generation device 200 when the CPU 201 executes a estimation algorithm generation program stored in the RAM 202.

The experimental data acquirer 211 acquires experimental data from the substrate processing apparatus 300. The experimental data includes a processing condition, a processing result ER representing a result of the film process executed by the substrate processing apparatus 300 on the substrate W according to the processing condition, and a processing type representing presence or absence of the back-surface discharge process. The processing result ER is represented by the difference between film thicknesses obtained before and after execution of the film process at each of a plurality of different positions in the radial direction of the substrate W.

The estimation algorithm generator 213 receives the experimental data from the experimental data acquirer 211. The estimation algorithm generator 213 generates an estimation algorithm using the experimental data, and outputs the generated estimation algorithm to the transmitter 215. Details of the estimation algorithm generator 213 will be described below. The transmitter 215 transmits the estimation algorithm generated by the estimation algorithm generator 213 to the information processing apparatus 100.

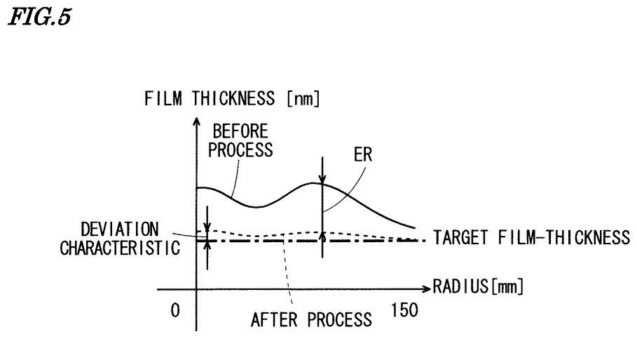

Here, the processing result ER will be described. FIG. 5 is a diagram for explaining the processing result ER. In FIG. 5, the ordinate indicates a film thickness, and the abscissa indicates a position in the radial direction of the substrate. The origin of the abscissa indicates the center of the substrate. The film thickness of a film formed on the substrate W before the substrate W is processed by the substrate processing apparatus 300 is indicated by the solid line. In the film process, the substrate processing apparatus 300 applies the etching liquid according to a processing condition, thereby adjusting the film thickness of the film formed on the substrate W. The film thickness of a film formed on the substrate W after the film process is executed by the substrate processing apparatus 300 is indicated by the dotted line.

The difference between the film thickness of the film formed on the substrate W before execution of the process by the substrate processing apparatus 300 and the film thickness of the film formed on the substrate W after execution of the process by the substrate processing apparatus 300 is a processing result ER (etching amount). In other words, the processing result ER indicates a film thickness by which the film thickness is reduced at each of the plurality of different positions in the radial direction of the substrate W by the film process executed by the substrate processing apparatus 300.

In the above-mentioned film process of the substrate processing apparatus 300, in a case in which the back-surface discharge process is executed by the back-surface nozzle 312 (see FIG. 1), a temperature of the substrate W is changed by the etching liquid discharged through the back-surface nozzle 312. Therefore, presence or absence of the back-surface discharge process influences an amount of film thickness to be reduced by the film process. Therefore, the processing result ER varies depending on presence or absence of the back-surface discharge process.

In the following description, a processing condition according to which the back-surface discharge process is not executed in the film process is referred to as a first processing condition, and a processing condition according to which the back-surface discharge process is executed in the film process is referred to as a second processing condition. The second processing condition is obtained when a back-surface discharge condition of the back-surface discharge process is added to the first processing condition. Further, in regard to the processing result ER, a processing result ER obtained when the substrate processing apparatus 300 executes the film process according to the first processing condition is referred to as a first processing result ER1, and a processing result ER obtained when the substrate processing apparatus 300 executes the film process according to the second processing condition is referred to as a second processing result ER2.

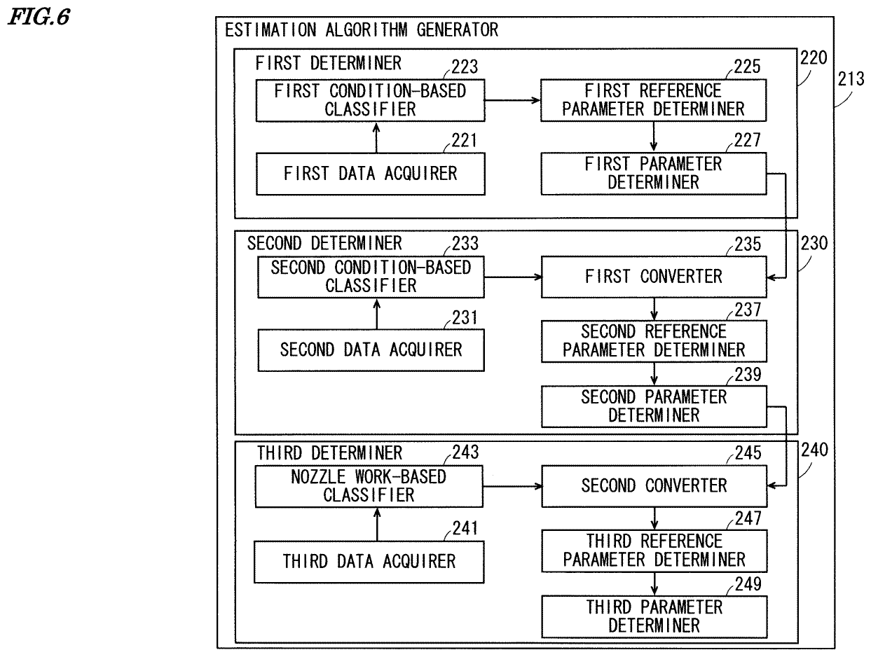

Next, the detailed configuration of the estimation algorithm generator 213 will be described below. FIG. 6 is a diagram showing one example of the functions for generating an estimation algorithm that takes the back-surface discharge process into account among functions of the estimation algorithm generator according to the present embodiment. With reference to FIG. 6, the estimation algorithm generator 213 includes a first determiner 220, a second determiner 230 and a third determiner 240.

The first determiner 220 identifies the first function F1(x) having a position x of the substrate W as a variable based on the first processing condition and the first processing result ER1. Specifically, the first determiner 220 includes a first data acquirer221, a first condition-based classifier 223, a first reference parameter determiner 225 and a first parameter determiner 227. The first data acquirer 221 acquires, from the experimental data acquirer 211, a plurality of first datasets each of which includes a first processing condition and a first processing result ER1 that is obtained when the film process is executed according to the first processing condition.

The first condition-based classifier 223 classifies the plurality of first datasets acquired by the first data acquirer 221 into a plurality of groups based on the processing conditions. The first condition-based classifier 223 classifies a plurality of first datasets having the same first processing conditions into the same group. Further, the first condition-based classifier 223 may define, in regard to each of a plurality of items of a first processing condition, a plurality of ranges obtained by division of the valid range of the item, define a plurality of groups that are combinations of the plurality of ranges for the plurality of items, and classify the plurality of first datasets into one of the plurality of groups. For example, in a case in which three ranges are provided for each of a temperature of the etching liquid, a concentration of the etching liquid and a flow rate of the etching liquid, twenty seven groups are defined. In this case, the plurality of first datasets are classified into any of twenty seven groups.

The first reference parameter determiner 225 determines, for each of the plurality of groups defined by the first condition-based classifier 223, the first function F1(x) that approximates one or more first datasets classified into the group. Here, the first function F1(x) will be described.

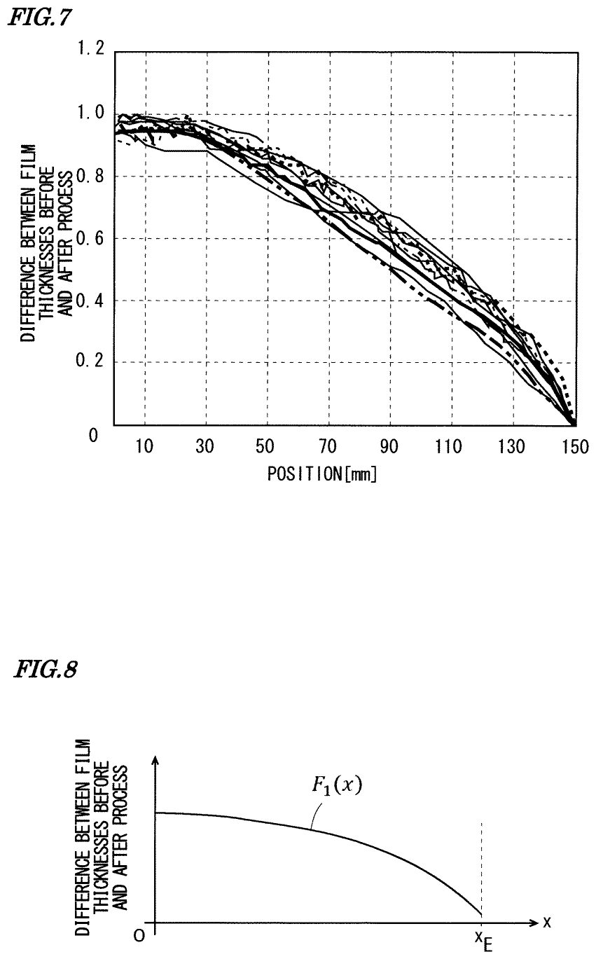

FIG. 7 is a diagram showing one example of a first processing result. In FIG. 7, the ordinate indicates a difference between film thicknesses obtained before and after the film process, and the abscissa indicates a position in a radial direction of the substrate W. The origin indicates the center O of the substrate. Further, the plurality of first processing results ER1 are normalized to zero to one. As shown in FIG. 7, when the etching liquid has different temperatures, difference concentrations and different flow rates, first processing results ER1 vary. As shown in FIG. 7, in regard to the plurality of first processing results ER1, the difference between film thicknesses obtained before and after the film process is large near the center O of the substrate W, and the closer a position is to the outer peripheral end portion of the substrate W, the smaller the difference between film thicknesses obtained before and after the film process.

FIG. 8 is a diagram showing the first function F1(x). The abscissa indicates a position in the radial direction of the substrate, and the ordinate indicates the difference between film thicknesses obtained before and after the film process. With reference to FIG. 8, the position indicated by XE on the abscissa represents the outer peripheral end portion of the substrate W. The first function F1(x) shown in FIG. 8 has been found by the inventors as a function approximating the first processing results ER1 shown in FIG. 7.

The first function F1(x) represents the difference between film thicknesses obtained before and after the film process at any position in the radial direction of the substrate W in a case in which the film process is executed on the substrate W according to a first processing condition. The first function F1(x) is expressed by the following formulation (1).

$$\begin{matrix}[ Formulation 1 ] & \\ {F}_{1} ( x ) = - α {x}^{{n}_{1}} + β & ( 1 )\end{matrix}$$

The first function F1(x) is expressed using a position x in the radial direction of the substrate as a variable, and using first reference parameters α and β. The first function F1(x) is an n1-th (n1 is a positive integer) function of the variable x.

With reference back to FIG. 6, the first reference parameter determiner 225 determines, for each of a plurality of groups, in other words, for each of a plurality of first processing conditions, a constant n1 and first reference parameters α and β with which the first function F1(x) most approximates a first processing result ER1. The constant n1 and the first reference parameters α and β are obtained by a regression analysis. The first reference parameter determiner 225 outputs, in regard to each of the plurality of groups, a set of a first processing condition, and first reference parameters α and β obtained in correspondence with the first processing condition, to the first parameter determiner 227.

For example, in regard to determination of a constant n1, the first reference parameter determiner 225 determines the constant n1 using least-squares method, with the constant n1 minimizing the error between a first processing result ER1 of each first dataset and the first function F1 (x). The first reference parameters α and β are determined by a regression analysis. For example, the first reference parameter determiner 225 compares an average value of the first processing result ER1 with an average value of the first function F1(x) of the formulation (1) for each first dataset, and compares the difference between a maximum value and a minimum value of the first processing result ER1 with the difference between a maximum value and a minimum value of the first function F1 (x) of the formulation (1). The first function F1(x) may be determined using a method such as a fluid analysis.

The first parameter determiner 227 receives a plurality of sets each of which includes a first processing condition and a first reference parameter from the first reference parameter determiner 225. The first parameter determiner 227 determines first parameters α1 to α3 and β1 to β3 by providing the plurality of sets each of which includes a first processing condition and a first reference parameter to a first sub-function expressed by the following formulations (2) and (3) to perform regression. In other words, the first parameter determiner 227 determines the first parameters α1 to α3 and β1 to β3 of a plurality of first sub-functions such that the values of the first parameters α1 to α3 and β1 to β3 of each of the plurality of first sub-functions are respectively close to the values of the first parameters α1 to α3 and β1 to β3 of each of the rest of the plurality of first sub-functions, with the plurality of first sub-functions being provided with a plurality of sets each of which includes a first processing condition and a first reference parameter.

$$\begin{matrix}[ Formulation 2 ] & \\ α = exp ( {α}_{1} T + {α}_{2} D + {α}_{3} ) & ( 2 )\end{matrix}$$

$$β = exp ( {β}_{1} T + {β}_{2} D + {β}_{3} ) \qquad ( 3 )$$

The first parameters α1 to α3 and β1 to β3 are values depending on a concentration of the etching liquid. Here, a first sub-function will be described. The first sub-function includes a function representing the relationship between a first reference parameter α and the first parameters α1 to α3 as expressed by the formulation (2), and a function representing the relationship between a first reference parameter β and the first parameters β1 to β3 as expressed by the formulation (3). The first sub-function has been found based on a qualitative tendency of a first processing result by the inventors as a function having a temperature of the etching liquid, a concentration of the etching liquid, and a flow rate of the etching liquid of a first processing condition as variables.

The first parameter determiner 227 receives sets each of which includes a first processing condition and first reference parameters α and β from the first reference parameter determiner 225, and the number of sets is equal to the number of first processing conditions. The first parameter determiner 227 determines the first parameters α1 to α3 and β1 to β3 in regard to a plurality of first processing conditions such that the values of the first parameters α1 to α3 and β1 to β3 in regard to each of the plurality of first processing conditions are respectively close to the values of the first parameters α1 to α3 and β1 to β3 in regard to each of the rest of the plurality of first processing conditions.

Specifically, the first parameter determiner 227 substitutes the first reference parameters α and β and a first processing condition into the first sub-function in regard to each of the plurality of first processing conditions. Thus, the formulations (2) and the formulations (3) each number of which is equal to the number of the first processing conditions are generated. The first parameter determiner 227 determines the first parameters α1 to α3 of the formulations (2) the number of which is equal to the number of first processing conditions such that the values of the first parameters α1 to α3 of each of the formulations (2) are respectively close to the values of the first parameters α1 to α3 of each of the rest of the formulations (2). The first parameter determiner 227 determines the first parameters β1 to β3 of the formulations (3) the number of which is equal to the number of first processing conditions such that the values of the first parameters β1 to β3 of each of the formulations (3) are respectively close to the values of the first parameters β1 to β3 of each of the rest of the formulations (3). A method such as the least squares method may be used for determination of the first parameters α1 to α3 and β1 to β3 by the first parameter determiner 227. Thus, the first function F1 (x) is determined. The first parameter determiner 227 provides the determined first function F1 (x) to the second determiner 230.

The second determiner 230 generates a second function F2(x) based on a second processing condition and a second processing result ER2. The second function F2(x) has a position of the substrate W as a variable. The second determiner 230 identifies the second function F2(x) based on the second processing condition and the second processing result FR2.

Specifically, the second determiner 230 includes a second data acquirer 231, a second condition-based classifier 233, a first converter 235, a second reference parameter determiner 237 and a second parameter determiner 239. The second data acquirer 231 acquires, from the experimental data acquirer 211, a plurality of second datasets each of which includes a second processing condition and a second processing result ER2.

The second condition-based classifier 233 classifies the plurality of second datasets acquired by the second data acquirer 231 into a plurality of groups based on processing conditions. The second condition-based classifier 233 classifies the plurality of second datasets having the same second processing condition into the same group. Further, the second condition-based classifier 233 may define, in regard to each of a plurality of items of a second processing condition, a plurality of ranges obtained by division of the valid range of the item, define a plurality of groups that are combinations of the plurality of ranges for the plurality of items, and classify the plurality of second datasets into one of the plurality of groups. For example, in a case in which three ranges are provided for each of a temperature of the etching liquid, a concentration of the etching liquid, a flow rate of the etching liquid and a rotation speed of the substrate W, eighty one groups are defined. In this case, the plurality of second datasets are classified into one of eighty one groups.

The second reference parameter determiner 237 determines, for each of the plurality of groups defined by the second condition-based classifier 233, a second function F2(x) based on one or more second datasets classified into the group. Here, the second function F2(x) will be described.

The determination procedure for the second function F2(x) is as follows. The film process is executed according to a plurality of second processing conditions respectively having different temperatures of the etching liquid, different concentrations of the etching liquid, different flow rates of the etching liquid and different rotation speeds of the substrate, so that a plurality of second processing results ER2 are obtained. A value of a second processing result ER2 at a position in the radial direction of the substrate W is expressed as follows using the first function F1(x) and the second function F2(x) expressed by the formulation (1).

$$\begin{matrix}[ Formulation 3 ] & \\ ER 2 = {F}_{1} ( x ) \cdot {F}_{2} ( x ) & ( 4 )\end{matrix}$$

Here, when the formulation (4) is transformed, the second function F2 (x) is equal to a value obtained by division of a value of a second processing result ER2 by the first function F1 (x). Because the second function F2 (x) is a value obtained by division of the second processing result ER2 by the first function F1(x), it can be said that the second function F2(x) represents the influence of the back-surface discharge process. Hereinafter, the influence of the back-surface discharge process is referred to as a first influence degree.

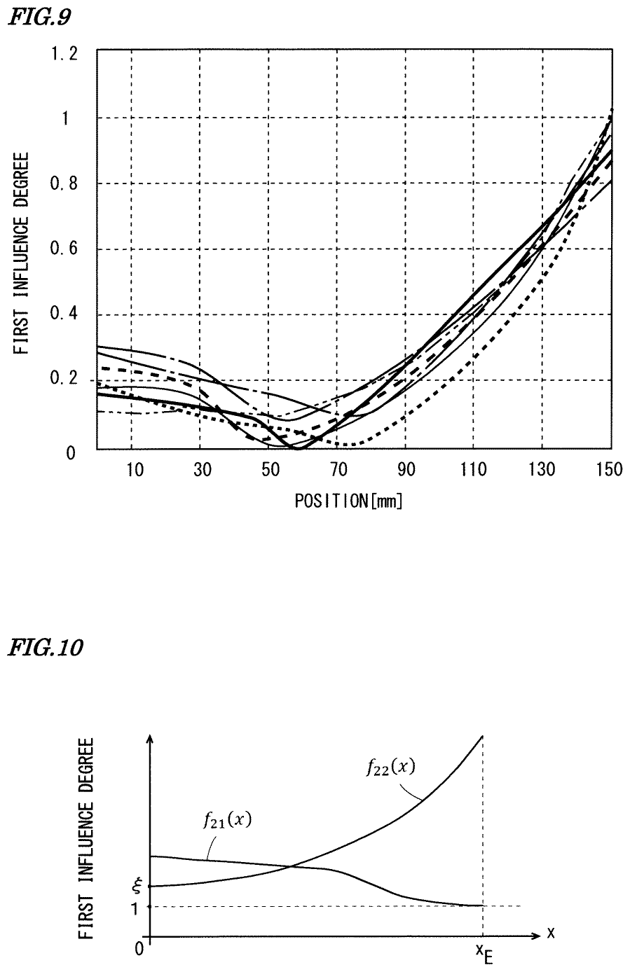

FIG. 9 is a diagram showing a first influence degree for each position in the radial direction of the substrate W. The ordinate indicates a first influence degree, and the abscissa indicates a position in the radial direction of the substrate W. Further, the first influence degree is normalized to zero to one. As shown in FIG. 9, when second processing conditions are different, first influence degrees differ.

In regard to each of a plurality of groups defined by the second condition-based classifier 233, the first converter 235 outputs, to the second reference parameter determiner 237, a first influence degree obtained by division of a second processing result ER2 of one or more second datasets classified into the group by the first function F1 (x) determined by the first determiner 220.

FIG. 10 is a diagram showing one example of the second function F2(x). With reference to FIG. 10, the abscissa indicates a position in the radial direction of the substrate, and the ordinate indicates a first influence degree. The position indicated by XE on the abscissa represents the outer peripheral end portion of the substrate W. The second function F2(x) shown in FIG. 10 has been found by the inventors as a function approximating the first influence degree shown in FIG. 9.

The second function F2(x) is expressed by the following formulation (5).

$$\begin{matrix}[ Formulation 4 ] & \\ {F}_{2} ( x ) = {f}_{21} ( x ) \cdot {f}_{22} ( x ) & ( 5 )\end{matrix}$$

$${f}_{21} ( x ) = γ sech ( δ x ) + 1 \qquad ( 6 )$$

$${f}_{22} ( x ) = ε {x}^{{n}_{2}} + ξ \qquad ( 7 )$$

The second function F2(x) is expressed by a product of a first component function f21(x) expressed by the formulation (6) and a second component function f22(x) expressed by the formulation (7). The first component function f21 (x) is a hyperbolic function in regard to a variable x indicating a position in the radial direction of the substrate W. The second component function f22(x) is an n2-th (n2 is a positive constant) function of a variable x. The first component function f21(x) and the second component function f22(x) are respectively expressed using a position in the radial direction of the substrate W as a variable x, and using second reference parameters γ, δ, ε and ξ. In other words, the second function F2(x) is expressed using a position x in the radial direction of the substrate W as a variable X and using the second reference parameters γ, δ, ε and ξ.

With reference back to FIG. 6, the second reference parameter determiner 237 determines, for each of a plurality of groups, in other words, for each of a plurality of second processing conditions, a constant n2 and second reference parameters γ, δ, ε and ξ that cause the second function F2(x) expressed by the formulation (5) to best approximate the first influence degree shown in FIG. 9. The constant n2 and the second reference parameters γ, δ, ε and ξ are obtained by a regression analysis.

One example of determination of the second reference parameters γ, δ, ε and ξ will be described. First, the second reference parameter determiner 237 regresses ξ of the second component function f22(x) based on the lowest value of a plurality of first influence degrees calculated by the first converter 235. Subsequently, based on the shape of the first influence degree in the vicinity of the outside the substrate W shown in FIG. 10, it is found that the influence of the first component function f21(x) is small in the vicinity of the outside of the substrate W. As such, the second reference parameter determiner 237 regresses ε of the second component function f22(x) in the vicinity of the outside of the substrate W of each of the plurality of first influence degrees. Thus, the second component function f22(x) is determined. Subsequently, the plurality of first influence degrees are normalized to zero to one, and the influence of γ is eliminated. In this state, δ is regressed from the shape near the center O of the substrate W of the plurality of normalized first influence degrees. The normalization of the plurality of first influence degrees is canceled with 6 regressed, and γ is regressed based on the shape of the plurality of first influence degrees. Thus, the first component function f21(x) is determined.

The second reference parameter determiner 237 outputs, to the second parameter determiner 239, a set of a second processing condition, and second reference parameters γ, δ, ε and ξ obtained in correspondence with the second processing condition, in regard to each of a plurality of groups.

The second parameter determiner 239 receives a set of a second processing condition and second reference parameters from the second reference parameter determiner 237. The second parameter determiner 239 provides a plurality of sets each of which includes a second processing condition and second reference parameters to the second sub-function expressed by the formulations (8) to (11) to regress second parameters γ1 to γ4, δ1 to δ4, ε1 to ε4 and ξ1 to ξ4.

$$\begin{matrix}[ Formulation 5 ] & \\ γ = exp ( {γ}_{1} C + {γ}_{2} D + {γ}_{3} R + {γ}_{4} ) & ( 8 )\end{matrix}$$

$$δ = exp ( {δ}_{1} C + {δ}_{2} D + {δ}_{3} R + {δ}_{4} ) \qquad ( 9 )$$

$$ε = exp ( {ε}_{1} C + {ε}_{2} D + {ε}_{3} R + {ε}_{4} ) \qquad ( 10 )$$

$$ξ = exp ( {ξ}_{1} C + {ξ}_{2} D + {ξ}_{3} R + {ξ}_{4} ) \qquad ( 11 )$$

The second parameters γ1 to γ4, δ1 to δ4, ε1 to ε4 and ξ1 to ξ4 are values depending on a temperature of the etching liquid. Here, the second sub-function will be described. The second sub-function includes a function representing the relationship between the second reference parameter γ and the second parameters γ1 to γ4 as expressed by the formulation (8), a function representing the relationship between the second reference parameter δ and the second parameters δ1 to δ4 as expressed by the formulation (9), a function representing the relationship between the second reference parameter ε and the second parameters ε1 to ε4 as expressed by the formulation (10), and a function representing the relationship between the second reference parameter ξ and the second parameters ξ1 to ξ4 as expressed by the formulation (11). The second sub-function has been found based on a qualitative tendency of a first influence degree by the inventors as a function having a temperature of the etching liquid, a concentration of the etching liquid, a flow rate of the etching liquid and a rotation speed of the substrate W of a second processing condition as variables.

The second parameter determiner 239 receives sets each of which includes a second processing condition and second reference parameters γ, δ, ε and ξ from the second reference parameter determiner 237, and the number of sets is equal to the number of second processing conditions. In regard to the plurality of second processing conditions, the second parameter determiner 239 determines the second parameters γ1 to γ4, δ1 to δ4, ε1 to ε4 and ξ1 to ξ4 in regard to a plurality of second processing conditions such that the values of the second parameters γ1 to γ4, δ1 to δ4, ε1 to ε4 and ξ1 to ξ4 in regard to each of the plurality of second processing conditions are respectively close to the values of the second parameters γ1 to γ4, δ1 to δ4, ε1 to ε4 and ξ1 to ξ4 in regard to each of the rest of the plurality of second processing conditions.

Specifically, in regard to each of a plurality of second processing conditions, the second parameter determiner 239 substitutes second reference parameters γ, δ, ε and ξ and a second processing condition into a second sub-function. Thus, the formulations (8) to (11) each number of which is equal to the number of the second processing conditions are generated. The second parameter determiner 239 determines the second parameters γ1 to γ4 of the formulations (8) the number of which is equal to the number of second processing conditions such that the values of the second parameters γ1 to γ4 of each of the formulations (8) are respectively close to the values of the second parameters γ1 to γ4 of each of the rest of the formulations (8). Further, the second parameter determiner 239 determines the second parameters δ1 to δ4 of the formulations (9) the number of which is equal to the number of second processing conditions such that the values of the second parameters δ1 to δ4 of each of the formulations (9) are respectively close to the values of the second parameters δ1 to δ4 of each of the rest of the formulations (9). Further, the second parameter determiner 239 determines the second parameters ε1 to ε4 of the formulations (10) the number of which is equal to the number of second processing conditions such that the values of the second parameters ε1 to ε4 of each of the formulations (10) are respectively close to the values of the second parameters ε1 to ε4 of each of the rest of the formulations (10). Further, the second parameter determiner 239 determines the second parameters ξ1 to ξ4 of the formulations (11) the number of which is equal to the number of second processing conditions such that the values of the second parameters ξ1 to ξ4 of each of the formulations (11) are respectively close to the values of the second parameters ξ1 to ξ4 of each of the rest of the formulations (11). A method such as the least squares method may be used for determination of the second parameters γ1 to γ4, δ1 to δ4, ε1 to ε4 and ξ1 to ξ4 by the second parameter determiner 239. The second parameter determiner 239 provides the second function F2 (x) to the third determiner 240.

Here, details of a second processing result ER2 obtained in the film process of the substrate processing apparatus 300 will be described. In the film process executed by the substrate processing apparatus 300, the etching liquid is supplied from the obverse-surface nozzle 311 to the substrate W on which a film is formed. Specifically, in the film process, the etching liquid comes into contact with the film formed on the substrate W, thereby removing the film formed on the substrate W. Here, when the film process is started, the obverse-surface nozzle 311 moves from the outer peripheral end portion of the substrate W toward the center of the substrate W. Therefore, there is a period during which the etching liquid does not reach the film formed on the substrate W in a period during which the obverse-surface nozzle 311 moves from the outer peripheral end portion of the substrate W to the center of the substrate W. Therefore, a period of time during which the etching liquid does not come into contact with the film after the start of the film process influences a processing result of the film process.

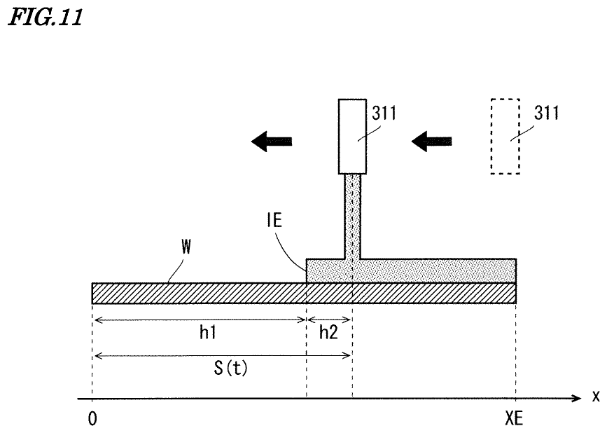

FIG. 11 is a diagram for explaining the behavior of the etching liquid with respect to the work of the obverse-surface nozzle 311 of the substrate processing apparatus 300. FIG. 11 shows the cross section from the outer peripheral end portion XE of the substrate W to the center O of the substrate W in the cross section of the substrate W in the moving range of the obverse-surface nozzle 311. When the film process is started, the obverse-surface nozzle 311 discharges the etching liquid toward the substrate W while moving in the horizontal direction from the outer peripheral end portion XE of the substrate W toward the center O of the substrate W.

The obverse-surface nozzle 311 is located above the outer peripheral end portion XE of the substrate W in advance before the start of the film process. When an instruction for starting the film process is provided to the substrate processing apparatus 300, the substrate W rotates, and the obverse-surface nozzle 311 discharges the etching liquid from above the outer peripheral end portion XE of the rotating substrate W. Thus, the etching liquid is supplied to the vicinity of the obverse surface of the outer peripheral end portion XE of the substrate W.

Next, the obverse-surface nozzle 311 moves from a position above the outer peripheral end portion XE of the substrate W toward a position above the center O of the substrate W while discharging the etching liquid. The moving speed of the obverse-surface nozzle 311 during a processing period of time of the present embodiment is defined in advance. In this case, the relative position of the obverse-surface nozzle 311 with respect to the substrate W is indicated by S(t) with a point t in time as a variable. In other words, the distance between the center O of the substrate W and the obverse-surface nozzle 311 is indicated by S(t) with t as a variable. The variable t represents a period of time elapsed since the film process is started. S(t) is a variable condition.

When the etching liquid is supplied to the substrate W, a large portion of the supplied etching liquid moves toward the outside of the substrate W by a centrifugal force of the rotating substrate W. On the other hand, the etching liquid that has collided with the substrate W due to being discharged by the obverse-surface nozzle 311 spreads in the horizontal direction on the substrate W. Therefore, a portion of the etching liquid supplied to the substrate W moves inwardly of the substrate W from a position where the etching liquid collides with the substrate W. At this time, the distance between the center O of the substrate W, and an outer peripheral end IE of the etching liquid that has moved toward the center of the substrate is referred to as a first distance h1. Further, the distance between the outer peripheral end IE of the etching liquid that has moved inwardly and a position where the etching liquid collides with the substrate W is referred to as a second distance h2. Because being values relating to the distance S(t) between the center O of the substrate W and the obverse-surface nozzle 311, the first distance h1 and the second distance h2 can be expressed by a first distance function h1(t) and a second distance function h2(t) using a variable t.

When the outer peripheral end IE of the etching liquid reaches the center O of the substrate W because the obverse-surface nozzle 311 moves toward the position above the center O of the substrate W, the etching liquid is supplied to the entire substrate W due to a centrifugal force of the rotating substrate W. Thereafter, the obverse-surface nozzle 311 moves toward the position above the outer peripheral end portion opposite to the outer peripheral end portion XE with respect to the center O of the substrate W.

In this manner, there is a period of time during which the etching liquid is not actually supplied to each position in the radial direction of the substrate W in a period during which the outer peripheral end IE of the etching liquid supplied to the substrate W moves from the outer peripheral end portion XE to the center O of the substrate W with the movement of the obverse-surface nozzle 311.

With reference back to FIG. 6, the third determiner 240 generates a third function H(x) that takes the back-surface discharge process into account based on a second processing condition and a second processing result ER2. The second processing condition includes a variable condition. In regard to the third function H(x) that takes the back-surface discharge process into account, a position in the radial direction of the substrate W is used as a variable x. The third determiner 240 identifies the third function H(x) that takes the back-surface discharge process into account based on the second processing condition and the second processing result ER2.

Specifically, the third determiner 240 includes a third data acquirer 241, a nozzle work-based classifier 243, a second converter 245, a third reference parameter determiner 247 and a third parameter determiner 249. The third data acquirer 241 acquires, from the experimental data acquirer 211, a plurality of second datasets each of which includes a second processing condition and a second processing result ER2.

The nozzle work-based classifier 243 classifies the plurality of second datasets acquired by the third data acquirer 241 into a plurality of groups based on variable conditions. The nozzle work-based classifier 243 classifies a plurality of second datasets having the same variable condition into the same group.

The third reference parameter determiner 247 and the third parameter determiner 249 determine, for each of the plurality of groups defined by the nozzle work-based classifier 243, a third function H(x) that takes the back-surface discharge process into account based on one or more second datasets classified into the group. Here, the third function H(x) that takes the back-surface discharge process into account will be described.

The determination procedure for the third function H(x) that takes the back-surface discharge process into account is as follows. The film process is executed according to a plurality of second conditions, so that a plurality of second processing results are obtained. The plurality of second processing conditions respectively have different temperatures of the etching liquid, different concentrations of the etching liquid, different flow rates of the etching liquid, and different rotation speeds of the substrate W, and have different variable conditions each of which is represented by a relative position of the obverse-surface nozzle 311 with respect to the substrate W, with the relative position varying over time. The value of a second processing result ER2 at a position in the radial direction of the substrate W is expressed as follows using the first function F1(x) expressed by the formulation (1), the second function F2(x) and the third function H(x) that takes the back-surface discharge process into account.

$$\begin{matrix}[ Formulation 6 ] & \\ ER 2 = {F}_{1} ( x ) \cdot {F}_{2} ( x ) \cdot H ( x ) & ( 12 )\end{matrix}$$

Here, when the formulation (12) is transformed, the third function H(x) that takes the back-surface discharge process into account is equal to a value obtained by division of the value of a second processing result ER2 by the first function F1 (x) and the second function F2 (x). Therefore, it can be said that a value obtained by division of the value of a second processing result ER2 by the first function F1(x) and the second function F2(x) indicates the extent to which a period of time during which the etching liquid is not actually supplied to the substrate W by the nozzle work in a processing time influences a second processing result ER2. Hereinafter, a value obtained by division of the value of a second processing result ER2 by the first function F1(x) and the second function F2(x) is referred to as a second influence degree (or a coverage rate of the etching liquid).

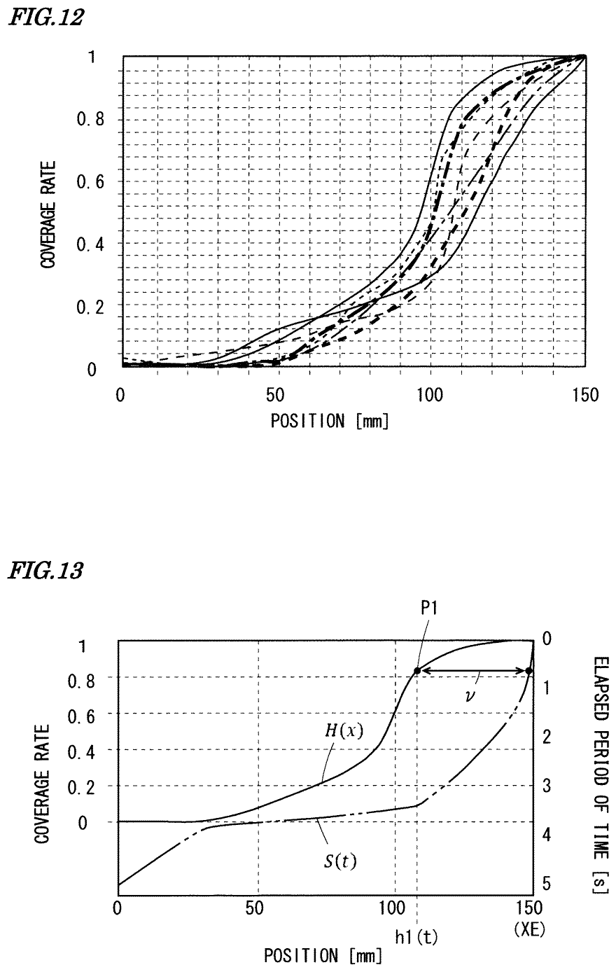

FIG. 12 is a diagram showing, based on variable conditions, coverage rates obtained based on a plurality of second processing results ER2. The ordinate indicates a coverage rate, and the abscissa indicates a position in the radial direction of the substrate W. In addition, the coverage rate is normalized to zero to one. As shown in FIG. 12, when variable conditions are different, coverage rates are different.

The second converter 245, for each of the plurality of groups defined by the nozzle work-based classifier 243, calculates a second influence degree by division of a second processing result ER2 of one or more second datasets classified into the group by the first function F1(x) determined by the first determiner 220 and the second function F2(x) determined by the second determiner 230, and outputs the calculated second influence degree to the third reference parameter determiner 247.

FIG. 13 is a diagram showing one example of the third function H(x). With reference to FIG. 3, the abscissa indicates a position in the radial direction of the substrate, the first ordinate on the left indicates a coverage rate, and a second ordinate on the right indicates an elapsed period of time since the start of the film process. The second ordinate indicates an elapsed period of time flowing from the top to the bottom. The third function H(x) is indicated by the solid line. Further, S(t) indicating a position of the obverse-surface nozzle 311 with respect to the substrate W is indicated by the one-dot and dash line. When an elapsed period of time is zero, the film process is started. The third function H(x) shown in FIG. 13 has been found by the inventors as a function approximating the second influence degree shown in FIG. 12.

The third function H(x) that takes the back-surface discharge process into account is expressed by the following formulation (13).

$$\begin{matrix}[ Formulation 7 ] & \\ H ( x ) = \{ \begin{matrix}1 & ( {h}_{1} ( {t}_{delay} ) \leq x ) \\ \frac{{h}_{1}^{- 1} ( x )}{{t}_{proc} - {t}_{delay}} & ( {h}_{1} ( {t}_{delay} ) > x )\end{matrix} & ( 13 )\end{matrix}$$

$${h}_{1} ( t ) = S ( t ) - v ( {t}_{delay} < t < {t}_{center} ) \qquad ( 14 )$$

$$v = exp ( {v}_{1} R + {v}_{2} D + {v}_{3} {x}^{- 1} + {v}_{4} ) \qquad ( 15 )$$

Here, _in a period during which the outer peripheral end IE of the etching liquid supplied to the substrate W moves from the outer peripheral end portion XE to the center O of the substrate W, in the first distance function h1(t), letting tcenter be a point in time at which the obverse-surface nozzle 311 arrives at the center O of the substrate W for the first time, and letting tdelay be a period of time from the time when the film process is started until the time when the etching liquid is actually supplied to the substrate W, the first distance function h1(t) is valid with tdelay<t<tcenter. The first distance function h1(t) can be expressed by the formulation (14) using the position S(t) of the obverse-surface nozzle 311 at a point t in time and a third reference parameter ν. An inverse function h1⁻¹(x) of the first distance function h1(t) represents a period of time during which the etching liquid is present at a position x on the substrate W. The third reference parameter ν indicates the distance from a position where the etching liquid collides with the substrate W (a position below the obverse-surface nozzle 311) to the outer peripheral end of the etching liquid.

The third sub-function expressed by the formulation (15) represents the third reference parameter ν using a variable x indicating a position in the radial direction of the substrate W. The third sub-function is an exponential function in regard to the variable x indicating a position in the radial direction of the substrate W, and is expressed using third parameters ν1 to ν4. The third sub-function has been found based on a qualitative tendency of a second influence degree by the inventors as a function having a flow rate of the etching liquid and a rotation speed of the substrate W of a second processing condition as variables.

The third function H(x) that takes the back-surface discharge process of the formulation (13) into account represents a coverage rate of the etching liquid. At a point in time of tdelay at which the supply of the etching liquid to the substrate W is actually started, it is not necessary to take the third function H(x) into account in regard to a position at which the etching liquid has already reached. Therefore, the third function H(x) having the variable x that is equal to or larger than the first distance function h1(tdelay) is expressed by one.

On the other hand, the third function H(x) having a variable x smaller than the first distance function h1 (tdelay) is obtained when the inverse function h1⁻¹(x) of the first distance function h1(t) is divided by tproc-tdelay indicating a period of time during which the etching solution is present on the substrate W. Here, tproc represents an elapsed period of time from the start of the film process to the end of the film process, and tdelay represents a period of time from the start of the film process to the actual supply of the etching liquid to the substrate W. Therefore, the third function H(x) is expressed using a position x in the radial direction of the substrate as a variable, and using the third reference parameters ν1 to ν4.

As for a second processing result ER2, the etching liquid is sufficiently supplied to a position in the radial direction of the substrate W that is larger than the first distance h1. Accordingly, it is assumed that the shape of a second processing result ER2 when the parameter x is the first distance h1 changes largely. Therefore, attention is paid to a point β1 corresponding to an inflection point of the third function H(x). At an inflection point, the change rate of the coverage rate changes rapidly. Therefore, an inflection point is a feature point of the third function H(x). A value of the point β1 on the abscissa indicates a value of the first distance function h1(t). Further, the distance from the point β1 to S(t) on the abscissa corresponds to a third reference parameter ν indicating a second distance h2. In the present embodiment, a third parameter is determined because the third reference parameter ν at the inflection point P is obtained.

With reference back to FIG. 6, the third reference parameter determiner 247 determines a value of the third reference parameter ν for each of a plurality of groups, in other words, for each of a plurality of variable conditions, with respect to the coverage rate obtained based on the plurality of second processing results ER2 shown in FIG. 12. The third parameter determiner 249 determines respective third parameters v1 to v4 for a plurality of groups, in other words, for each of a plurality of second processing conditions. The third parameter determiner 249 provides a third reference parameter and a second processing condition to the third sub-function expressed by the formulation (15) to perform a regression analysis, thereby determining the third parameters v1 to v4. In other words, the third reference parameter determiner 247 determines the third parameters ν1 to ν4 of the formulations (15) the number of which is equal to the number of second processing conditions such that the values of the third parameters ν1 to ν4 of each of the formulations (15) are respectively close to the values of the third parameters ν1 to ν4 of each of the rest of the formulations (15).

The estimation algorithm generator 213 generates an estimation algorithm through the above-mentioned series of works. An estimation algorithm is indicated by a product of the first function F1 (x) determined by the first determiner 220, the second function F2(x) determined by the second determiner 230, and the third function H(x) that takes the back-surface discharge process into account and is determined by the third determiner 240.

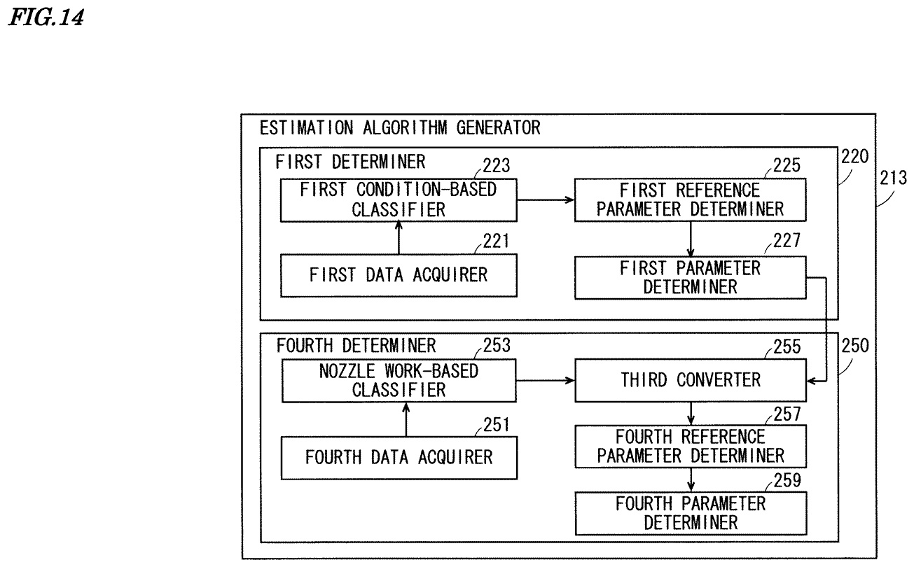

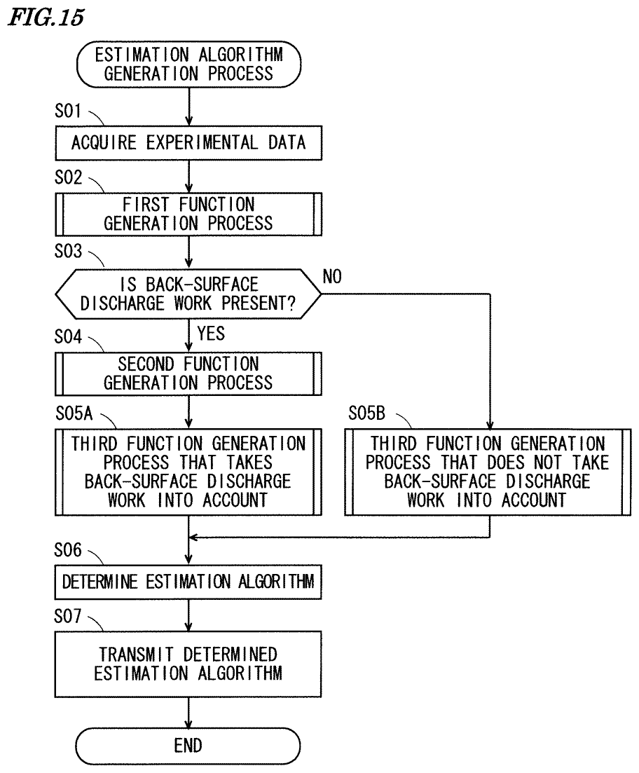

FIG. 14 is a diagram showing one example of the functions for generating an estimation algorithm that does not take the back-surface discharge process into account among the functions of the estimation algorithm generator. With reference to FIG. 14, the estimation algorithm generator 213 includes a first determiner 220 and a fourth determiner 250. The function of the first determiner 220 is similar to the above-mentioned function. Therefore, a description thereof will not be repeated.

The fourth determiner 250 generates a third function H(x) that does not take the back-surface discharge process into account based on a first processing condition and a first processing result ER1. Specifically, the fourth determiner 250 includes a fourth data acquirer 251, a nozzle work-based classifier 253, a third converter 255, a fourth reference parameter determiner 257 and a fourth parameter determiner 259.

The fourth data acquirer 251 acquires, from the experimental data acquirer 211, a plurality of first datasets each of which includes a first processing condition and a first processing result ER1. A first processing condition includes a variable condition.

The nozzle work-based classifier 253 classifies the plurality of first datasets acquired by the fourth data acquirer 251 into a plurality of groups based on variable conditions. The nozzle work-based classifier 253 classifies a plurality of first datasets having the same variable conditions into the same group.

The fourth reference parameter determiner 257 and the fourth parameter determiner 259 determines, for each of the plurality of groups defined by the nozzle work-based classifier 253, a third function H(x) that does not take the back-surface discharge process into account based on the one or more first datasets classified into the group.

The determination procedure for the third function H(x) that does not take the back-surface discharge process into account is as follows. The film process is executed according to a plurality of first processing conditions, so that a plurality of first processing results ER1 are obtained. The plurality of first processing conditions respectively have different temperatures of the etching liquid, different concentrations of the etching liquid, different flow rates of the etching liquid and different rotation speeds of the substrate W, and have different variable conditions each of which is represented by a relative position of the obverse-surface nozzle 311 with respect to the substrate W, with the relative position varying over time. A value of a first processing result ER1 at a position in the radial direction of the substrate W is expressed as follows using the first function F1 (x) expressed by the formulation (1), and the third function H(x) that does not take the back-surface discharge process into account.

$$\begin{matrix}[ Formulation 8 ] & \\ ER 2 = {F}_{1} ( x ) \cdot H ( x ) & ( 12 A )\end{matrix}$$

Here, when the formulation (12A) is transformed, the third function H(x) that does not take the back-surface discharge process into account is equal to a value obtained by division of a value of a first processing result ER1 by the first function F1 (x). Therefore, it can be said that a value obtained by division of a value of a first processing result ER1 by the first function F1 (x) represents the extent to which a period of time during which the etching liquid is not actually supplied to the substrate W in the nozzle work in a processing period of time influences a first processing result ER1. Hereinafter, a value obtained by division of a value of a first processing result ER1 by the first function F1(x) is referred to as a third influence degree.

The third converter 255, for each of a plurality of groups defined by the nozzle work-based classifier 253, calculates a third influence degree by dividing a first processing result ER1 of one or more first datasets classified into the group by the first function F1(x) determined by the first determiner 220, and outputs the calculated third influence degree to the fourth reference parameter determiner 257.

The fourth reference parameter determiner 257 determines a value of the third reference parameter v for each of the plurality of groups with respect to the third influence degree obtained based on the first processing result ER1, in other words, for each of the plurality of variable conditions. In regard to a method of determining a value of the third reference parameter v, the same method as the determination method executed by the third reference parameter determiner 247 is used. The fourth parameter determiner 259 determines respective third parameters v1 to v4 for a plurality of groups, in other words, for each of a plurality of first processing conditions. The fourth parameter determiner 259 provides a third reference parameter and a first processing condition to the third sub-function expressed by the formulation (15) to perform a regression analysis, and determines the third parameters v1 to v4. In other words, the fourth parameter determiner 259 determines the third parameters ν1 to ν4 of the formulations (15) the number of which is equal to the number of first processing conditions such that the values of the third parameters ν1 to ν4 of each of the formulations (15) are respectively close to the values of the third parameters ν1 to ν4 of each of the rest of the formulations (15).

Through the series of work, the estimation algorithm generator 213 can generate an estimation algorithm represented by a product of the first function F1(x) and the third function H(x) that does not take the back-surface discharge process into account and is determined by the fourth determiner 250.

Here, with reference back to FIG. 5, it is desirable that the thickness of a film formed by the substrate processing apparatus 300 is uniform over the entire surface of the substrate W. Therefore, a target film-thickness is defined for the process executed by the substrate processing apparatus 300. The target film-thickness is indicated by the one-dot and dash line. A deviation characteristic represents the difference between a thickness of the film formed on the substrate W after the process by the substrate processing apparatus 300 and the target film-thickness. The deviation characteristic includes the difference generated at each of the plurality of positions in the radial direction of the substrate W.

With reference back to FIG. 4, the information processing apparatus 100 includes a processing condition determiner 151, a receiver 155, an estimator 159, an evaluator 161 and a processing condition transmitter 163. The functions included in the information processing apparatus 100 are implemented by execution, by the CPU 101 included in the information processing apparatus 100, of a processing condition determination program stored in the RAM 102. The receiver 155 receives an estimation algorithm transmitted from the estimation algorithm generation device 200, and outputs the received estimation algorithm to the estimator 159.

The processing condition determiner 151 determines a processing condition for the substrate W to be processed by the substrate processing apparatus 300, and outputs the processing condition including a variable condition including the back-surface discharge process to the estimator 159.

The estimator 159 estimates an etching profile based on a processing condition including a variable condition. Specifically, the estimator 159 estimates an etching profile based on a processing condition that includes a variable condition and is received from the processing condition determiner 151, and outputs the etching profile to the evaluator 161.

The evaluator 161 evaluates the etching profile received from the estimator 159 and outputs an evaluation result to the processing condition determiner 151. In detail, the evaluator 161 acquires the film-thickness characteristic obtained before the substrate W to be processed by the substrate processing apparatus 300 is processed. The evaluator 161 calculates the film-thickness characteristic estimated to be obtained after the etching process based on the etching profile received from the estimator 159 and the film-thickness characteristic obtained before the substrate W is processed, and compares the calculated film-thickness characteristic with a target film-thickness characteristic. When the comparison result satisfies an evaluation criterion, a processing condition determined by the processing condition determiner 151 is output to the processing condition transmitter 163. For example, the evaluator 161 calculates a deviation characteristic (see FIG. 5) and determines whether the deviation characteristic satisfies the evaluation criterion. The deviation characteristic is the difference between the film-thickness characteristic of the substrate W obtained after the etching process and the target film-thickness characteristic. The evaluation criterion can be arbitrarily defined. For example, in regard to the deviation characteristic, the evaluation criterion may be that the maximum value of differences is equal to or smaller than a threshold value, or that the average of differences is equal to or smaller than the threshold value.

The processing condition transmitter 163 transmits the processing condition that includes a variable condition and is determined by the processing condition determiner 151 to the control device 10 of the substrate processing apparatus 300. The substrate processing apparatus 300 processes the substrate W according to the processing condition including the variable condition.

In a case in which an evaluation result does not satisfy the evaluation criterion, the evaluator 161 outputs the evaluation result to the processing condition determiner 151. The evaluation result includes a film-thickness characteristic estimated to be obtained after the etching process or the difference between a film-thickness characteristic estimated to be obtained after the etching process and the target film-thickness characteristic.

In response to receiving the evaluation result from the evaluator 161, the processing condition determiner 151 determines a new processing condition for estimation to be made by the estimator 159. Using design of experiments, pairwise testing or Bayesian inference, the processing condition determiner 151 selects one of a plurality of prepared processing conditions each of which includes a variable condition, and transmits the selected processing condition to the estimator 159.

The processing condition determiner 151 searches for a processing condition including a variable condition using Bayesian inference, by way of example. For example, in a case in which a plurality of evaluation results are output by the evaluator 161, a plurality of sets each of which includes a processing condition including a variable condition, and an evaluation result, are obtained. Based on the likelihood of the etching profile for each of the plurality of sets, a processing condition that causes the film thickness to be uniform or a processing condition that causes the difference between a film-thickness characteristic estimated to be obtained after an etching process and a target film-thickness characteristic to be minimum is searched.

Specifically, the processing condition determiner 151 searches for a processing condition that causes an objective function to be minimized. The objective function represents the uniformity of film thickness of a film or represents the coincidence between the film-thickness characteristic of a film and a target film-thickness characteristic. For example, the objective function represents, using a parameter, the difference between a film-thickness characteristic estimated to be obtained after the etching process and a target film-thickness characteristic. The parameter here is a corresponding variable condition. The corresponding variable condition is used for estimating an etching profile using an estimation algorithm. The processing condition determiner 151 selects a variable condition which is a parameter determined by search among a plurality of variable conditions, and determines the selected variable condition and a processing condition.

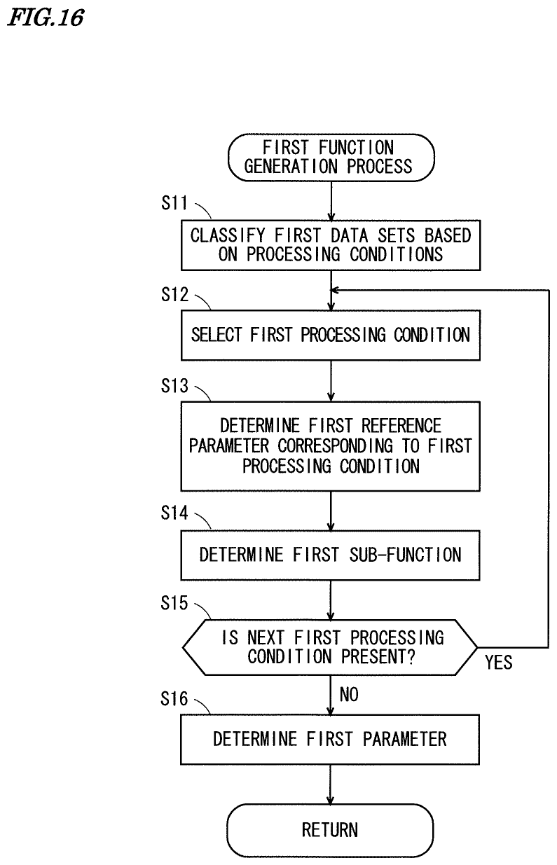

FIG. 15 is a flowchart showing one example of a flow of an estimation algorithm generation process. The estimation algorithm generation process is executed by the CPU 201 included in the estimation algorithm generation device 200 when the CPU 201 executes an estimation algorithm generation program stored in the RAM 202.

With reference to FIG. 15, the CPU 201 included in the estimation algorithm generation device 200 acquires experimental data (step S01). The CPU 201 controls the input-output I/F 107 to acquire the experimental data from the substrate processing apparatus 300. The experimental data may be acquired when the experimental data recorded in a recording medium such as the CD-ROM 209 is read by the storage device 104. The experimental data includes a plurality of first datasets and a plurality of second datasets. A first dataset includes a first processing condition and a first processing result ER1. A second dataset includes a second processing condition and a second processing result ER2.

In the next step S02, a first function generation process is executed, and the process proceeds to the step S03. While details of the first function generation process will be described below, the first function generation process is a process of generating a first function F1(x) based on the plurality of first datasets. In the step S03, whether the back-surface discharge process is executed in the film process of the substrate processing apparatus 300 is determined.

In a case in which it is determined in the step S03 that the back-surface discharge process is executed in the film process of the substrate processing apparatus 300, the process proceeds to the step S04. A second function generation process is executed in the step S04, and the process proceeds to the step S05A. While details of the second function generation process will be described below, the second function generation process is a process of generating a second function F2(x) based on the plurality of second datasets. A third function generation process that takes the back-surface discharge process into account is executed in the step S05A, and the process proceeds to the step S06. While details of the third function generation process that takes the back-surface discharge process into account will be described below, the third function generation process is a process of generating a third function H(x) based on the plurality of second datasets.

In a case in which it is determined in the step S03 that the back-surface discharge process is not executed in the film process of the substrate processing apparatus 300, the process proceeds to the step S05B. The third function generation process that does not take the back-surface discharge process into account is executed in the step S05B, and the process proceeds to the step S06. While details of the third function generation process that does not take the back-surface discharge process into account will be described below, the third function generation process is a process of generating a third function H(x) based on the plurality of first datasets.

In the step S06, the CPU 201 determines an estimation algorithm. In a case in which the process proceeds from the step S05A, an estimation algorithm is determined using the first function determined in the step S02, the second function determined in the step S04, and the third function that takes the back-surface discharge process into account and is determined in the step S05A. In a case in which the process proceeds from the step S05B, an estimation algorithm is determined using the first function determined in the step S01 and the third function that does not take the back-surface discharge process into account and is determined in the step S05B. In the next step S07, the CPU 201 transmits the determined estimation algorithm to the information processing apparatus 100, and the process ends.

FIG. 16 is a flowchart showing one example of a flow of a first function determination process. The above-mentioned formulations (1) to (3) are stored in advance in the storage device 204 of the estimation algorithm generation device 200. First, the CPU 201 acquires a plurality of first datasets from experimental data, and classifies the plurality of acquired first datasets into a plurality of groups based on processing conditions (step S11).

Next, the CPU 201 selects a first processing condition by selecting one group to be processed from among the plurality of groups. The CPU 201 determines a first reference parameter corresponding to the selected first processing condition (step S13), and the process proceeds to the step S14. Specifically, the CPU 201 provides the first processing condition to the formulation (1) stored in the storage device 204 and determines first reference parameters α and β corresponding to the first processing condition and a constant n1 by regressing to a first processing result ER1.

Subsequently, the CPU 201 determines a first sub-function (step S14), and the process proceeds to the step S15. Here, the CPU 201 determines the first sub-function with respect to the first processing condition by substituting the first reference parameters α and β determined in the step S13 and the first processing condition selected to be processed into the first sub-functions (formulations (2) and (3)) stored in the storage device 204. In the step S15, whether a first processing condition not selected to be processed is present is determined. If a selected first processing condition is present, the process returns to the step S12. If not, the process proceeds to the step S16.

The steps S12 to S14 are repeated as many times as the number of a plurality of first processing conditions, so that a plurality of first sub-functions respectively corresponding to the plurality of first processing conditions are determined. In the step S16, the CPU 201 determines first parameters α1 to α3 and β1 to β3. Thereafter, the process returns to the estimation algorithm generation process. For example, the CPU 201 determines the first parameters α1 to α3 and β1 to β3 by performing a regression analysis on the plurality of first sub-functions respectively corresponding to the plurality of first processing conditions. In other words, the first parameters α1 to α3 and β1 to β3 of the plurality of first sub-functions are determined such that the values of the first parameters α1 to α3 and β1 to β3 of each of the plurality of first sub-functions are respectively close to the values of the first parameters α1 to α3 and β1 to β3 of each of the rest of the plurality of first sub-functions. The first parameters α1 to α3 and β1 to β3 are defined, so that the first function F1(x) expressed by the formulation (1) is defined using the formulations (2) and (3). Therefore, by providing any first processing condition to the first function F1 (x), it is possible to estimate a processing condition representing the difference between film thicknesses obtained before and after a process in a case in which the substrate processing apparatus 300 executes the film process according to the first processing condition.

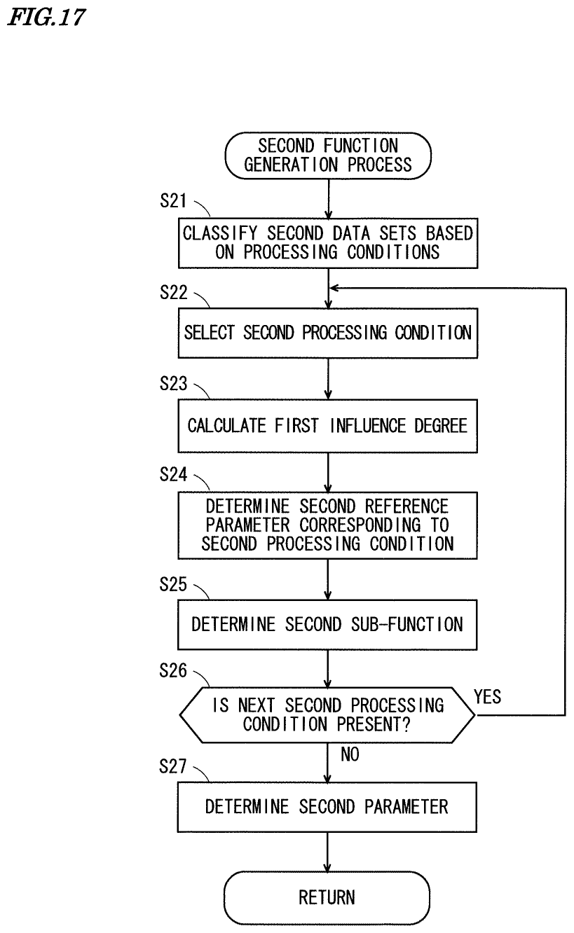

FIG. 17 is a flowchart showing one example of a flow of a second function determination process. The above-mentioned formulations (4) to (7) are stored in advance in the storage device 204 of the estimation algorithm generation device 200. First, the CPU 201 acquires a plurality of second datasets from experimental data, and classifies the plurality of acquired second datasets into a plurality of groups based on processing conditions (step S21).

Next, the CPU 201 selects a second processing condition by selecting one group to be processed from among the plurality of groups (step S22). The CPU 201 calculates a first influence degree using a second processing result ER2 obtained based on the selected second processing condition and a first function F1(x) generated by the first function generation process (step S23). The CPU 201 determines a second reference parameter corresponding to the selected second processing condition (step S24), and the process proceeds to the step S25. Specifically, the CPU 201 provides the second processing condition to the formulations (6) and (7) stored in the storage device 204, and determines second reference parameters γ, δ, ε and ξ corresponding to the second processing condition and a constant n2 by regressing such that the formulations (6) and (7) approximate the calculated first influence degree.

Subsequently, the CPU 201 determines a second sub-function (step S25), and the process proceeds to the step S26. Here, the CPU 201 determines a second sub-function with respect to a second processing condition by substituting the second reference parameters γ, δ, ε and ξ determined in the step S24 and the second processing condition selected to be processed into the second sub-functions (formulations (8), (9), (10) and (11)) stored in the storage device 204. In the step S26, whether a second processing condition not selected to be processed is present is determined. If a non-selected second processing condition is present, the process returns to the step S22. If not, the process proceeds to the step S27.

The steps S22 to S25 are repeated as many times as the number of a plurality of second processing conditions, so that a plurality of second sub-functions respectively corresponding to the plurality of second processing conditions are determined. In the step S27, the CPU 201 determines second parameters γ1 to γ4, δ1 to δ4, ε1 to ε4 and ξ1 to ξ4. Thereafter, the process returns to the estimation algorithm generation process. For example, the CPU 201 determines the second parameters γ1 to γ4, δ1 to δ4, ε1 to ε4 and ξ1 to ξ4 by performing a regression analysis on the plurality of second sub-functions respectively corresponding to the plurality of second processing conditions. Therefore, the second parameters γ1 to γ4, δ1 to δ4, ε1 to ε4 and ξ1 to ξ4 in regard to the plurality of second sub-functions are determined such that the values of the second parameters γ1 to γ4, δ1 to δ4, ε1 to ε4 and ξ1 to ξ4 in regard to each of the plurality of second sub-functions are respectively close to the values of the second parameters γ1 to γ4, δ1 to δ4, ε1 to ε4 and ξ1 to ξ4 in regard to each of the rest of the plurality of second sub-functions. When the second parameters γ1 to γ4, δ1 to δ4, ε1 to ε4 and ξ1 to ξ4 are defined, the second function F2(x) expressed by the formulation (5) is defined using the formulations (6) to (7) and the formulations (8) to (11). Therefore, by providing any second processing condition to the second function F2(x), it is possible to estimate a processing condition representing the difference between film thicknesses obtained before and after a process in a case in which the substrate processing apparatus 300 executes the film process according to the second processing condition.

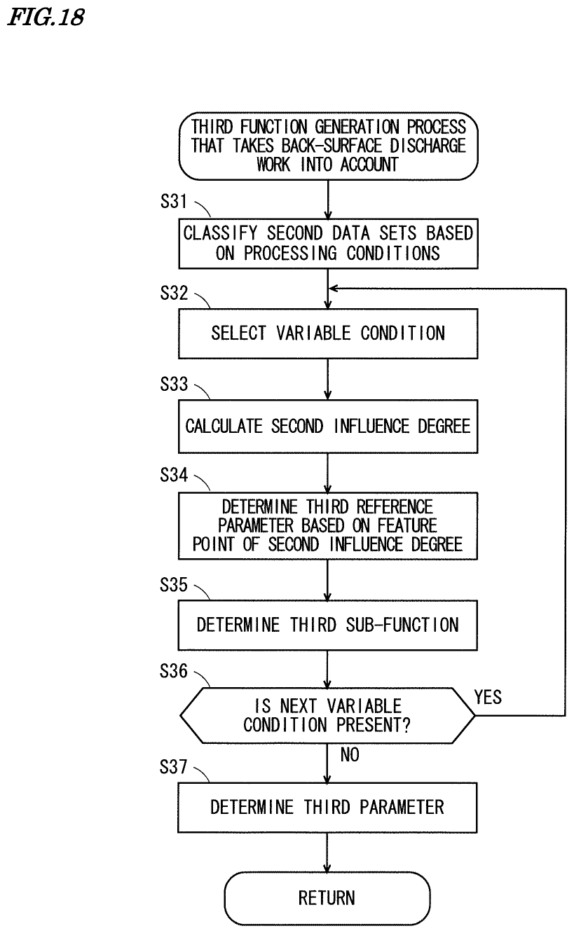

FIG. 18 is a flowchart showing one example of a flow of a third function determination process that takes the back-surface discharge process into account. The above-mentioned formulations (12) to (15) are stored in advance in the storage device 204 of the estimation algorithm generation device 200. First, the CPU 201 acquires a plurality of second datasets from experimental data, and classifies the plurality of acquired second datasets into a plurality of groups based on processing conditions (step S31).

Next, the CPU 201 selects a variable condition by selecting one group to be processed from among the plurality of groups (step S32). The CPU 201 calculates a second influence degree (coverage rate) using a second processing result ER2 obtained based on a second processing condition corresponding to the selected variable condition, a first function F1(x) generated in the first function generation process, and a second function F2(x) generated in the second function generation process (step S33). The CPU 201 determines a third reference parameter ν corresponding to the variable condition (step S34), and the process proceeds to the step S35. Specifically, the CPU 201 sets an inflection point of the calculated second influence degree as a feature point. The inflection point is determined through second-order differentiation of the second influence degree. Further, the CPU 201 determines the distance between the inflection point and a position of the obverse-surface nozzle 311 in the radial direction of the substrate W as the third reference parameter ν.

Subsequently, the CPU 201 determines a third sub-function (step S35), and the process proceeds to the step S36. Here, the CPU 201 substitutes the third reference parameters v determined in the step S34, a variable condition selected to be processed, and the second processing condition corresponding to the variable condition into the third sub-function (formulation (15)) stored in the storage device 204. Thus, the third sub-function corresponding to the variable condition is determined. In the step S36, whether a variable condition not selected to be processed is present is determined. If an unselected variable condition is present, the process returns to the step S32. If not, the process proceeds to the step S37.

The steps S32 to S35 are repeated as many times as the number of a plurality of variable conditions, so that a plurality of third sub-functions respectively corresponding to the plurality of variable conditions are determined. In the step S37, the CPU 201 determines third parameters v1 to v4. Thereafter, the process returns to the estimation algorithm generation process. Specifically, the CPU 201 determines the third parameters ν1 to ν4 by performing a regression analysis on the plurality of third sub-functions respectively corresponding to the plurality of variable conditions. In other words, the third parameters ν1 to ν4 of the plurality of third sub-functions are determined such that the values of the third parameters ν1 to ν4 of each of the plurality of third sub-functions are respectively close to the values of the third parameters ν1 to ν4 of each of the rest of the plurality of third sub-functions. By determination of the third parameters ν1 to ν4, the third function H(x) that takes the back-surface discharge process into account and is expressed by the formulation (13) is defined using the formulations (14) and (15). Therefore, by providing any variable condition to the third function H(x) that takes the back-surface discharge process into account, it is possible to estimate a processing result representing the difference between film thicknesses obtained before and after a process in a case in which the substrate processing apparatus 300 executes the film process (including the back-surface discharge process) according to the variable condition.

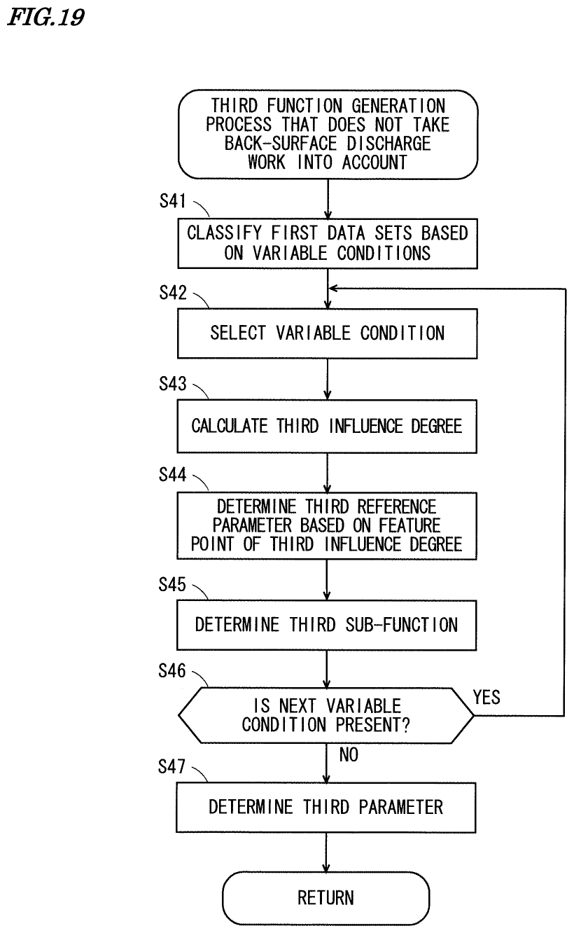

FIG. 19 is a flowchart showing one example of a flow of a third function determination process that does not take the back-surface discharge process into account. As described above, the formulation (12A) and the formulations (13) to (15) are stored in advance in the storage device 204 of the estimation algorithm generation device 200. First, the CPU 201 acquires a plurality of first datasets from experimental data, and classifies the plurality of acquired first datasets into a plurality of groups based on processing conditions (step S41).

Next, the CPU 201 selects a variable condition by selecting one group to be processed from among a plurality of groups (step S42). The CPU 201 calculates a third influence degree (coverage rate) using a first processing result ER1 obtained based on a first processing condition corresponding to the selected variable condition, and a first function F1 (x) generated in the first function generation process (step S43), The CPU 201 determines a third reference parameter v corresponding to the variable condition (step S44), and the process proceeds to the step S45. Specifically, the CPU 201 sets an inflection point of the calculated third influence degree as a feature point. The inflection point is determined through second-order differentiation of the third influence degree. Further, the CPU 201 determines the distance between the inflection point and a position of the obverse-surface nozzle 311 in the radial direction of the substrate W as the third reference parameter ν.

Subsequently, the CPU 201 determines a third sub-function (step S45), and the process proceeds to the step S46. Here, the CPU 201 substitutes the third reference parameter v determined in the step S44, a variable condition selected to be processed, and a first processing condition corresponding to the variable condition into the third sub-function (formulation (15)) stored in the storage device 204. Thus, the third sub-function corresponding to the variable condition is determined. In the step S46, whether a variable condition not selected to be processed is present is determined. If an unselected variable condition is present, the process returns to the step S42. If not, the process proceeds to the step S47.

The steps S42 to S45 are repeated as many times as the number of a plurality of variable conditions, so that a plurality of third sub-functions respectively corresponding to the plurality of variable conditions are determined. In the step S47, the CPU 201 determines third parameters v1 to v4. Thereafter, the process returns to the estimation algorithm generation process. Specifically, the CPU 201 determines the third parameters v1 to v4 by performing a regression analysis on the plurality of third sub-functions respectively corresponding to the plurality of variable conditions. In other words, the third parameters ν1 to ν4 of the plurality of third sub-functions are determined such that the values of the third parameters ν1 to ν4 of each of the plurality of third sub-functions are respectively close to the values of the third parameters ν1 to ν4 of each of the rest of the plurality of third sub-functions. By determination of the third parameters ν1 to ν4, the third function H(x) that does not take the back-surface discharge process into account and is expressed by the formulation (13) is defined using the formulations (14) and (15). Therefore, by providing any variable condition to the third function H(x) that does not take the back-surface discharge process into account, it is possible to estimate a processing result representing the difference between film thicknesses obtained before and after a process in a case in which the substrate processing apparatus 300 executes the film process (not including the back-surface discharge process) according to the variable condition.

### (4) Effects of Embodiment

With the above-mentioned estimation algorithm generation device 200, first reference parameters α and β of a predetermined first function F1(x), and first parameters α1 to α3 and β1 to β3 are determined based on a plurality of first datasets each of which includes a first processing condition and a first processing result ER1. Thus, it is possible to adapt, for each substrate processing apparatus 300, the first function F1(x) for estimating a first processing result ER1 based on a first processing condition. Further, because a first processing result ER1 is calculated based on a first processing condition using a first function F1(x), credibility in regard to estimation of a first processing result ER1 using a first function F1 (x) is improved as compared to estimation of a first processing result ER1 using an inference model with poor explanatory properties such as a black box.

Further, a first sub-function is determined for each of a plurality of first processing conditions, and first parameters α1 to α3 and β1 to β3 in regard to the plurality of first processing conditions are determined such that the values of the first parameters α1 to α3 and β1 to β3 in regard to each of the plurality of first processing conditions are respectively close to the values of the first parameters α1 to α3 and β1 to β3 in regard to each of the rest of the plurality of first processing conditions. Therefore, the first function F1(x) can be easily obtained.

Further, second reference parameters γ, δ, ε and ξ and second parameters γ1 to γ4, δ1 to δ4, ε1 to ε4 and ξ1 to ξ4 of a predetermined second function F2(x) are determined based on a plurality of second datasets. A first influence degree is obtained by division of a second processing result ER2 by a value calculated when a second processing condition is provided to a first function F1 (x), thereby representing the extent to which the back-surface discharge process influences a second processing result ER2. Thus, a second function F2(x) for estimating the extent to which a process of supplying a processing liquid to the back surface of the substrate influences a second processing result ER2 can be adapted for each substrate processing apparatus.

Further, a second sub-function is determined for each of a plurality of second processing conditions, and second parameters γ1 to γ4, δ1 to δ4, ε1 to ε4 and ξ1 to ξ4 in regard to the plurality of second processing conditions are determined such that the values of second parameters γ1 to γ4, δ1 to δ4, ε1 to ε4 and ξ1 to ξ4 in regard to each of the plurality of second processing conditions are respectively close to the values of the second parameters γ1 to γ4, δ1 to δ4, ε1 to ε4 and ξ1 to ξ4 in regard to each of the rest of the plurality of second processing conditions. Thus, the second function F2 (x) can be easily obtained.

Further, a third reference parameter ν and third parameters ν1 to ν4 of a predetermined third function H(x) are determined based on a second influence degree. Because being a value obtained by division of a second processing result ER2 by a value calculated when a second processing condition is provided to a first function F1(x) and a value calculated when the second processing condition is provided to a second function F2(x), the second influence degree represents the extent to which movement of a position of the nozzle over time influences the second processing result ER2, with the nozzle supplying a processing liquid to the substrate. Therefore, it is possible to adapt, for each substrate processing apparatus, the third function H(x) for estimating the extent to which the movement of a position of the nozzle over time influences the second processing result ER2, with the nozzle supplying the processing liquid to the substrate.

Further, a third sub-function is determined for each of a plurality of variable conditions, and the third parameters v1 to v4 in regard to the plurality of variable conditions are determined such that the values of the third parameters v1 to v4 in regard to each of the plurality of variable conditions are respectively close to the values of the third parameters v1 to v4 in regard to each of the rest of the plurality of variable conditions. Therefore, the third function H1(x) can be easily obtained.

### (5) Other Embodiments

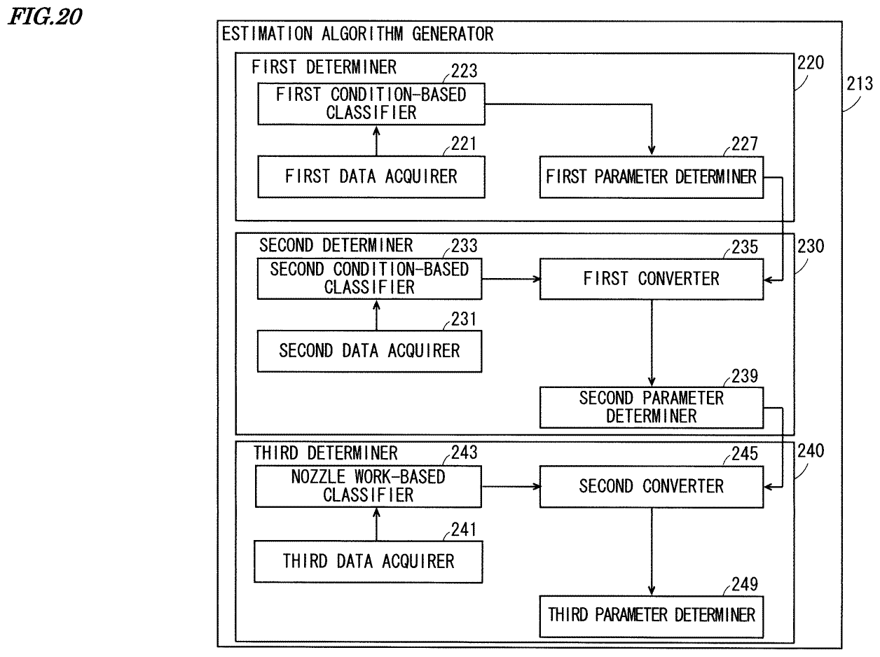

(5-1) FIG. 20 is a diagram showing one example of the functions of an estimation algorithm generator. The differences between the functions of the estimation algorithm generator of FIG. 6 and the estimation algorithm generator of FIG. 20 are as follows. The functions of the estimation algorithm generator of FIG. 20 does not have the first reference parameter determiner 225 of the first determiner 220, the second reference parameter determiner 237 of the second determiner 230 or the third reference parameter determiner 247 of the third determiner 240. In the formulation (1) of the above-mentioned embodiment, a first function F1 (x) is expressed using first reference parameters α and β. In the formulations (2) and (3), first reference parameters α and β are represented using first parameters α1 to α3 and β1 to β3 using a first sub-function. However, the present invention is not limited to this. For example, as expressed by the formulation (16), the first function F1(x) may be expressed using the first parameters α1 to α3 and β1 to β3 without involving the first sub-function.

$$\begin{matrix}[ Formulation 9 ] & \\ & ( 16 )\end{matrix}$$

$${F}_{1} ( x ) = - exp ( {α}_{1} T + {α}_{2} D + {α}_{3} ) {x}^{{n}_{1}} + exp ( {β}_{1} T + {β}_{2} D + {β}_{3} )$$

The first parameter determiner 227 of FIG. 20 determines a constant n1 and first parameters α1 to α3 and β1 to β1 with which the first function F1(x) expressed by the formulation (16) most approximates to a first processing result ER1. The constant n1 and the first parameters α1 to α3 and β1 to β3 are obtained by a regression analysis.

Further, in the formulations (5) to (7) of the above-mentioned embodiment, a second function F2(x) includes a first component function f21(x) and a second component function f22(x), and is expressed using second reference parameters γ, δ, ε and ξ of the first component function f21 (x) and the second component function f22(x), and the second reference parameters γ, δ, ε and ξ are expressed using second parameters γ1 to γ4, δ1 to δ4, ε1 to ε4 and ξ1 to ξ4 by the second sub-functions expressed by the formulations (8) to (11). However, the present invention is not limited to this. For example, as expressed by the following formulations (17) and (18), the first component function f21(x) and the second component function F22 (x) of the second function F2 (x) may be represented using the second parameters γ1 to γ4, δ1 to δ4, ε1 to ε4 and ξ1 to ξ4 without involving the second sub-function.

$$\begin{matrix}[ Formulation 10 ] & \\ & ( 17 )\end{matrix}$$

$${f}_{21} ( x ) = exp ( {γ}_{1} C + {γ}_{2} D + {γ}_{3} R + {γ}_{4} ) sech ( exp ( {δ}_{1} C + {δ}_{2} D + {δ}_{3} R + {δ}_{4} ) \cdot x ) + 1$$

$${f}_{22} ( x ) = exp ( {ε}_{1} C + {ε}_{2} D + {ε}_{3} R + {ε}_{4} ) \cdot {x}^{{n}_{2}} + exp ( {ξ}_{1} C + {ξ}_{2} D + {ξ}_{3} R + {ξ}_{4} ) \qquad ( 18 )$$

The second parameter determiner 239 of FIG. 20 determines a constant n2 and second parameters γ1 to γ4, δ1 to δ4, ε1 to ε4 and ξ1 to ξ4 with which the first component function f21(x) and the second component function f22(x) of the second function F2(x) expressed by the formulations (17) and (18) most approximate to a second processing result ER2. The constant n2 and the second parameters γ1 to γ4, δ1 to δ4, ε1 to ε4 and ξ1 to ξ4 are obtained by a regression analysis.

Further, in the formulation (13) of the above-mentioned embodiment, the third function H(x) is expressed using the inverse function h1⁻¹(x) of the first distance function h1(t), the first distance function h1 (x) is expressed using the third reference parameter v, the third reference parameter v is represented using the third parameters v1 to v4 by the third sub-function expressed by the formulation (15). However, the present invention is not limited to this. For example, as expressed by the following formulation (19), the first distance function h1(x) of the third function H(x) may be expressed using the third parameters ν1 to ν4 without involving the third sub-function.

$$\begin{matrix}[ Formulation 11 ] & \\ {h}_{1} ( x ) = x - exp ( {v}_{1} R + {v}_{2} D + {v}_{3} {x}^{- 1} + {v}_{4} ) & ( 19 )\end{matrix}$$

The third parameter determiner 249 in FIG. 20 determines the third parameters ν1 to ν4 with which the first distance function h1(x) of the third function H(x) expressed by the formulation (19) most approximates to a second processing result ER2. The third parameters ν1 to ν4 are obtained by a regression analysis.

(5-2) In the above-mentioned embodiment, an estimation algorithm generated by the estimation algorithm generator 213 of the estimation algorithm generation device 200 is input to the estimator 159 of the information processing apparatus 100, the estimator 159 inputs a processing condition including a variable condition to the estimation algorithm, and an etching profile output by the estimation algorithm is output to the evaluator 161, by way of example. However, the present invention is not limited to this. For example, an estimation algorithm including the first function F1(x), the second function F2(x) and the third function H(x) expressed by the formulations (1) to (15) may be stored in the estimator. In this case, it is possible to implement functions of the estimator 159 by inputting each parameter determined by the estimation algorithm generator 213 of the estimation algorithm generation device 200 to the estimator 159 of the information processing apparatus 100.

### (6) Overview of Embodiments

(Item 1) An estimation algorithm generation device according to one aspect of the present invention includes a first data acquirer that acquires a plurality of first datasets, and a first determiner that determines a first parameter by providing the plurality of first datasets to a predetermined first function to perform a regression analysis, wherein each of the plurality of first datasets includes a first processing result and a first processing condition, with the first processing result being obtained after a substrate processing apparatus executes a film process according to the first processing condition by supplying a processing liquid to an upper surface of a substrate on which a film is formed, the first processing result includes a difference between film thicknesses obtained before and after execution of the film process at each of a plurality of different positions in a radial direction of the substrate, and the first function expresses, using the first processing condition and the first parameter, a difference between film thicknesses obtained before and after execution of the film process at any position in the radial direction of the substrate.

With the above-mentioned estimation algorithm generation device according to item 1, because the first parameter of the predetermined first function is determined based on the plurality of first datasets each of which includes a first processing condition and a first processing result, it is possible to adapt, for each substrate processing apparatus, the first function for estimating a first processing result based on the first processing condition. Further, because the first processing result is calculated based on the first processing condition using the first function, credibility in regard to estimation of the first processing result using the first function is improved as compared to estimation of a first processing result using an inference model with poor explanatory properties such as a black box. As a result, it is possible to provide the estimation algorithm generation device capable of easily generating an estimation algorithm adapted for the substrate processing apparatus.
(Item 2) The estimation algorithm generation device according to item 1, wherein the first function may use a first reference parameter being expressed by a first sub-function, with the first sub-function using the first processing condition and the first parameter, and the first determiner may include a first reference parameter determiner that determines, in regard to each of the plurality of first processing conditions, the first reference parameter corresponding to the first processing condition by providing the first processing result corresponding to the first processing condition to the first function to perform a regression analysis, and a first parameter determiner that determines, in regard to each of the plurality of first processing conditions, the first parameter by providing the first processing condition and the first reference parameter to the first sub-function to perform a regression analysis, with the first reference parameter being determined in correspondence with the first processing condition.

With the estimation algorithm generation device according to item 2, the first sub-function is determined for each of the plurality of first processing conditions, and the first parameters in regard to the plurality of first processing conditions are determined such that the value of the first parameter in regard to each of the plurality of first processing conditions is close to the value of the first parameter in regard to each of the rest of the plurality of first processing condition. Therefore, the first function can be easily obtained.
(Item 3) The estimation algorithm generation device according to item 1, wherein the film process may include a back-surface discharge process of supplying a processing liquid to a back surface of the substrate, the estimation algorithm generation device may further include a second data acquirer that acquires a plurality of second datasets, and a second determiner that determines a second parameter by providing a first influence degree and a second processing condition corresponding to each of the plurality of second datasets to a predetermined second function to perform a regression analysis, in a case in which the substrate processing apparatus executes the film process including the back-surface discharge process, each of the plurality of second datasets may include a second processing result and the second processing condition, with the second processing result being obtained after the substrate processing apparatus executes the film process including the back-surface discharge process according to the second processing condition in which a back-surface discharge condition is added to the first processing condition, the second processing result may include a difference between film thicknesses obtained before and after execution of the film process including the back-surface discharge process, at each of a plurality of different positions in the radial direction of the substrate, the second function may express the first influence degree obtained by division of the second processing result by a value calculated when the second processing condition is provided to the first function, and the second function may express the first influence degree at any position in the radial direction of the substrate using the second processing condition and the second parameter.

With the estimation algorithm generation device according to item 3, the second parameter of the predetermined second function is determined based on the plurality of second datasets. Because being a value obtained by division of the second processing result by a value calculated when the second processing condition is provided to the first function, the first influence degree represents the extent to which the back-surface discharge process influences the second processing result. Thus, it is possible to adapt, for each substrate processing apparatus, the second function for estimating the extent to which the process influences the second processing result, with the process being the process of supplying the processing liquid to the back surface of the substrate.
(Item 4) The estimation algorithm generation device according to item 3, wherein the second function may use a second reference parameter expressed by a second sub-function, with the second sub-function using the second processing condition and the second parameter, the second determiner may include a second reference parameter determiner that determines, in regard to each of the plurality of second processing conditions, the second reference parameter corresponding to the second processing condition by providing the first influence degree corresponding to the second processing condition to the second function to perform a regression analysis, and a second parameter determiner that determines, in regard to the plurality of second processing conditions, the second parameter by providing the second processing condition and the second reference parameter to the second sub-function to perform a regression analysis, with the second reference parameter being determined in correspondence with the second processing condition.

With the estimation algorithm generation device according to item 4, the second sub-function is determined for each of the plurality of second processing conditions, and the second parameters in regard to the plurality of second processing conditions are determined such that the value of the second parameter in regard to each of the plurality of second processing conditions is close to the value of the second parameter in regard to each of the rest of the plurality of second processing conditions. Therefore, the second function can be easily obtained.
(Item 5) The estimation algorithm generation device according to item 3, wherein the substrate processing apparatus, in a case in which executing the film process including the back-surface discharge process, may move a position of a nozzle over time, with the nozzle supplying a processing liquid to the substrate, the second processing condition may include a variable condition representing a relative position of the nozzle with respect to the substrate, with the relative position varying over time, the estimation algorithm generation device may further include a third determiner that determines a third parameter by providing a second influence degree and the second processing condition to a predetermined third function to perform a regression analysis, with the second influence degree and the second processing condition corresponding to each of the plurality of variable conditions, the third function may express the second influence degree obtained by division of the second processing result by a value calculated when the second processing condition is provided to the first function and a value calculated when the second processing condition is provided to the second function, and the third function may express the second influence degree at any position in the radial direction of the substrate using the second processing condition and the third parameter.

With the estimation algorithm generation device according to item 5, the third parameter of the predetermined third function is determined based on the second influence degree. Because being a value obtained by division of the second processing result by a value calculated when the second processing condition is provided to the first function and a value calculated when the second processing condition is provided to the second function, the second influence degree represents the extent to which movement of a position of the nozzle over time influences the second processing result, with the nozzle supplying a processing liquid to the substrate. Therefore, it is possible to adapt, for each substrate processing apparatus, the third function for estimating the extent to which the process of moving a position of the nozzle over time influences the second processing result, with the nozzle supplying the processing liquid to the substrate.
(Item 6) The estimation algorithm generation device according to item 5, wherein the third function may use a third reference parameter expressed by a third sub-function, with the third sub-function using the second processing condition and the third parameter, the third determiner may include a third reference parameter determiner that determines, in regard to each of the plurality of variable conditions, the third reference parameter based on a feature point of the second influence degree corresponding to the variable condition, and a third parameter determiner that determines, in regard to each of the plurality of variable conditions, the third parameter by providing the third reference parameter and the second processing result to the third sub-function to perform a regression analysis, with the third reference parameter being determined in correspondence with the variable condition, and with the second processing result corresponding to the variable condition.

With the estimation algorithm generation device according to item 6, the third sub-function is determined for each of the plurality of variable conditions, and the third parameters in regard to the plurality of variable conditions are determined such that the value of the third parameter in regard to each of the plurality of variable conditions is close to the value of the third parameter in regard to each of the rest of the plurality of variable conditions. Therefore, the third function can be easily obtained.
(Item 7) The estimation algorithm generation device according to item 1 or 2, wherein the substrate processing apparatus, in a case in which executing the film process, may move a position of a nozzle over time, with the nozzle supplying a processing liquid to the substrate, the first processing condition may include a variable condition representing a relative position of the nozzle with respect to the substrate, with the relative position varying over time, the estimation algorithm generation device may further include a fourth determiner that determines a third parameter by providing a third influence degree and the first processing condition to a predetermined third function to perform a regression analysis, with the third influence degree and the first processing condition corresponding to each of the plurality of variable conditions, the third function may express the third influence degree obtained by division of the first processing result by a value calculated when the first processing condition is provided to the first function, and the third function may express, using the first processing condition and the third parameter, the third influence degree at any position in the radial direction of the substrate.

With the estimation algorithm generation device according to item 7, the third parameter of the predetermined third function is determined based on the third influence degree. Because being a value obtained by division of the first processing result by a value calculated when the first processing condition is provided to the first function, the third influence degree represents the extent to which the process of moving a position of the nozzle over time influences the first processing result, with the nozzle supplying the processing liquid to the substrate. Therefore, it is possible to adapt, for each substrate processing apparatus, the third function for estimating the extent to which the process of moving a position of the nozzle over time influences the first processing result, with the nozzle supplying the processing liquid to the substrate.
(Item 8) The estimation algorithm generation device according to item 7, wherein the third function may use a third reference parameter expressed by a third sub-function, with the third sub-function using the first processing condition and the third parameter, and the fourth determiner may include a fourth reference parameter determiner that determines, in regard to each of the plurality of variable conditions, the third reference parameter based on a feature point of the third influence degree corresponding to the variable condition, and a fourth parameter determiner that determines, in regard to each of the plurality of variable conditions, the third parameter by providing the third reference parameter and the first processing condition to the third sub-function to perform a regression analysis, with the third reference parameter being determined in correspondence with the variable condition, and with the first processing condition corresponding to the variable condition.

With the estimation algorithm generation device according to item 8, the third sub-function is determined for each of the plurality of variable conditions, and the third parameters in regard to the plurality of variable conditions are determined such that the value of the third parameter in regard to each of the plurality of variable conditions is close to the value of the third parameter in regard to each of the rest of the plurality of variable conditions. Therefore, the third function can be easily obtained.
(Item 9) An information processing apparatus according to another aspect of the present invention manages a substrate processing apparatus, wherein the substrate processing apparatus executes a film process by supplying a processing liquid to an upper surface of a substrate on which a film is formed, the information processing apparatus includes a processing condition determiner that determines a first processing condition for execution of the film process by the substrate processing apparatus, the estimation algorithm is a first function that calculates, using a first parameter, based on the first processing condition, a difference between film thicknesses obtained before and after the film process at any position in a radial direction of the substrate on which the substrate processing apparatus executes the film process, the first parameter is obtained by providing a plurality of first datasets to the first function to perform a regression analysis, each of the plurality of first datasets includes a first processing result and the first processing condition, with the first processing result being obtained after the substrate processing apparatus is driven according to the first processing condition and executes the film process, the first processing result includes a difference between film thicknesses obtained before and after execution of the film process at each of a plurality of different positions in the radial direction of the substrate, and the processing condition determiner, in a case in which the first processing result that is calculated based on a temporary processing condition using the estimation algorithm satisfies an allowable condition, determines a temporary first processing condition as the first processing condition for driving the substrate processing apparatus.

With the information processing apparatus according to item 9, in a case in which the first processing result satisfies the allowable condition, with the first processing result being calculated using the first function when the first processing condition is provided to the first function, the temporary first processing condition is determined as the first processing condition for driving the substrate processing apparatus. Therefore, it is possible to determine a plurality of temporary first processing conditions for the first processing result that satisfies the allowable condition. As a result, it is possible to present the plurality of appropriate processing conditions for the substrate processing apparatus that executes a complicated process.
(Item 10) An estimation algorithm generation method according to another aspect of the present invention includes a step of acquiring a plurality of first datasets, and a step of determining a first parameter by providing the plurality of first datasets to a first function to perform a regression analysis, wherein each of the plurality of first datasets includes a first processing result and a first processing condition, with the first processing result being obtained after a substrate processing apparatus executes a film process according to the first processing condition by supplying a processing liquid to an upper surface of a substrate on which a film is formed, the first processing result includes a difference between film thicknesses obtained before and after execution of the film process at each of a plurality of different positions in a radial direction of the substrate, and the first function that expresses, using the first processing condition and the first parameter, a difference between film thicknesses obtained before and after execution of the film process at any position in the radial direction of the substrate, is predetermined.

With the above-mentioned estimation algorithm generation method according to item 10, because the first parameter of the predetermined first function is determined based on the plurality of first datasets each of which includes a first processing condition and a first processing result, it is possible to adapt, for each substrate processing apparatus, the first function for estimating the first processing result based on the first processing condition. Further, because the first processing result is calculated based on the first processing condition using the first function, credibility in regard to estimation of the first processing result using the first function is improved as compared to estimation of a first processing result using an inference model with poor explanatory properties such as a black box.
(Item 11) A processing condition determination method according to another aspect of the present invention that is executed by an information processing apparatus managing a substrate processing apparatus, wherein the substrate processing apparatus executes a film process by supplying a processing liquid to an upper surface of a substrate on which a film is formed, the processing condition determination method includes a processing condition determination step of determining a first processing condition for execution of the film process by the substrate processing apparatus, the estimation algorithm is a first function for calculating a first processing result based on the first processing condition using a first parameter, the first processing result includes a difference between film thicknesses obtained before and after execution of the film process at each of a plurality of different positions in a radial direction of the substrate, the first parameter is obtained when a plurality of first datasets is provided to the first function and a regression analysis is performed, each of the plurality of first datasets includes the first processing result and the first processing condition, with the first processing result being obtained after the substrate processing apparatus executes the film process according to the first processing condition, and the processing condition determination step includes, in a case in which a first processing result that is calculated based on a temporary first processing condition using the estimation algorithm satisfies an allowable condition, determining the temporary first processing condition as the first processing condition for driving the substrate processing apparatus.

With the processing condition determination method according to item 11, in a case in which the first processing result satisfies the allowable condition, with the first processing result being calculated using the first function when the first processing condition is provided to the first function, the temporary first processing condition is determined as the first processing condition for driving the substrate processing apparatus. Therefore, it is possible to determine a plurality of temporary first processing conditions for the first processing result that satisfies the allowable condition. As a result, it is possible to present the plurality of appropriate processing conditions for the substrate processing apparatus that executes a complicated process.

1. An estimation algorithm generation device comprising a hardware processor, wherein the hardware processor
acquires a plurality of first datasets, and
determines a first parameter by providing the plurality of first datasets to a predetermined first function to perform a regression analysis,
each of the plurality of first datasets includes a first processing result and a first processing condition, with the first processing result being obtained after a substrate processing apparatus executes a film process according to the first processing condition by supplying a processing liquid to an upper surface of a substrate on which a film is formed,
the first processing result includes a difference between film thicknesses obtained before and after execution of the film process at each of a plurality of different positions in a radial direction of the substrate, and
the first function expresses, using the first processing condition and the first parameter, a difference between film thicknesses obtained before and after execution of the film process at any position in the radial direction of the substrate.

2. The estimation algorithm generation device according to claim 1, wherein
the first function uses a first reference parameter being expressed by a first sub-function, with the first sub-function using the first processing condition and the first parameter, and
determination of the first determiner includes
determining, in regard to each of the plurality of first processing conditions, the first reference parameter corresponding to the first processing condition by providing the first processing result corresponding to the first processing condition to the first function to perform a regression analysis, and
determining, in regard to each of the plurality of first processing conditions, the first parameter by providing the first processing condition and the first reference parameter to the first sub-function to perform a regression analysis, with the first reference parameter being determined in correspondence with the first processing condition.

3. The estimation algorithm generation device according to claim 1, wherein
the film process includes a back-surface discharge process of supplying a processing liquid to a back surface of the substrate,
the hardware processor further acquires a plurality of second datasets, and
determines a second parameter by providing a first influence degree and a second processing condition corresponding to each of the plurality of second datasets to a predetermined second function to perform a regression analysis,
in a case in which the substrate processing apparatus executes the film process including the back-surface discharge process, each of the plurality of second datasets includes a second processing result and the second processing condition, with the second processing result being obtained after the substrate processing apparatus executes the film process including the back-surface discharge process according to the second processing condition in which a back-surface discharge condition is added to the first processing condition,
the second processing result includes a difference between film thicknesses obtained before and after execution of the film process including the back-surface discharge process, at each of a plurality of different positions in the radial direction of the substrate,
the second function expresses the first influence degree obtained by division of the second processing result by a value calculated when the second processing condition is provided to the first function, and
the second function expresses the first influence degree at any position in the radial direction of the substrate using the second processing condition and the second parameter.

4. The estimation algorithm generation device according to claim 3, wherein
the second function uses a second reference parameter expressed by a second sub-function, with the second sub-function using the second processing condition and the second parameter,
determination of the second determiner includes determining,
in regard to each of the plurality of second processing conditions, the second reference parameter corresponding to the second processing condition by providing the first influence degree corresponding to the second processing condition to the second function to perform a regression analysis, and
determining, in regard to the plurality of second processing conditions, the second parameter by providing the second processing condition and the second reference parameter to the second sub-function to perform a regression analysis, with the second reference parameter being determined in correspondence with the second processing condition.

5. The estimation algorithm generation device according to claim 3, wherein
the substrate processing apparatus, in a case in which executing the film process including the back-surface discharge process, moves a position of a nozzle over time, with the nozzle supplying a processing liquid to the substrate,
the second processing condition includes a variable condition representing a relative position of the nozzle with respect to the substrate, with the relative position varying over time,
the hardware processor further determines a third parameter by providing a second influence degree and the second processing condition to a predetermined third function to perform a regression analysis, with the second influence degree and the second processing condition corresponding to each of the plurality of variable conditions,
the third function expresses the second influence degree obtained by division of the second processing result by a value calculated when the second processing condition is provided to the first function and a value calculated when the second processing condition is provided to the second function, and
the third function expresses the second influence degree at any position in the radial direction of the substrate using the second processing condition and the third parameter.

6. The estimation algorithm generation device according to claim 5, wherein
the third function uses a third reference parameter expressed by a third sub-function, with the third sub-function using the second processing condition and the third parameter,
determination of the third parameter includes determining,
in regard to each of the plurality of variable conditions, the third reference parameter based on a feature point of the second influence degree corresponding to the variable condition, and
determining, in regard to each of the plurality of variable conditions, the third parameter by providing the third reference parameter and the second processing result to the third sub-function to perform a regression analysis, with the third reference parameter being determined in correspondence with the variable condition, and with the second processing result corresponding to the variable condition.

7. The estimation algorithm generation device according to claim 1, wherein
the substrate processing apparatus, in a case in which executing the film process, moves a position of a nozzle over time, with the nozzle supplying a processing liquid to the substrate,
the first processing condition includes a variable condition representing a relative position of the nozzle with respect to the substrate, with the relative position varying over time,
the hardware processor further determines a third parameter by providing a third influence degree and the first processing condition to a predetermined third function to perform a regression analysis, with the third influence degree and the first processing condition corresponding to each of the plurality of variable conditions,
the third function expresses the third influence degree obtained by division of the first processing result by a value calculated when the first processing condition is provided to the first function, and
the third function expresses, using the first processing condition and the third parameter, the third influence degree at any position in the radial direction of the substrate.

8. The estimation algorithm generation device according to claim 7, wherein
the third function uses a third reference parameter expressed by a third sub-function, with the third sub-function using the first processing condition and the third parameter, and
determination of the third parameter includes determining,
in regard to each of the plurality of variable conditions, the third reference parameter based on a feature point of the third influence degree corresponding to the variable condition, and
determining, in regard to each of the plurality of variable conditions, the third parameter by providing the third reference parameter and the first processing condition to the third sub-function to perform a regression analysis, with the third reference parameter being determined in correspondence with the variable condition, and with the first processing condition corresponding to the variable condition.

9. An information processing apparatus managing a substrate processing apparatus,
the substrate processing apparatus executing a film process by supplying a processing liquid to an upper surface of a substrate on which a film is formed, and comprising a hardware processor, wherein
the hardware processor determines a first processing condition for execution of the film process by the substrate processing apparatus,
the estimation algorithm is a first function that calculates, using a first parameter, based on the first processing condition, a difference between film thicknesses obtained before and after the film process at any position in a radial direction of the substrate on which the substrate processing apparatus executes the film process,
the first parameter is obtained by providing a plurality of first datasets to the first function to perform a regression analysis,
each of the plurality of first datasets includes a first processing result and the first processing condition, with the first processing result being obtained after the substrate processing apparatus is driven according to the first processing condition and executes the film process,
the first processing result includes a difference between film thicknesses obtained before and after execution of the film process at each of a plurality of different positions in the radial direction of the substrate, and
determination of the first processing condition includes, in a case in which the first processing result that is calculated based on a temporary processing condition using the estimation algorithm satisfies an allowable condition, determining a temporary first processing condition as the first processing condition for driving the substrate processing apparatus.

10. An estimation algorithm generation method including:
acquiring a plurality of first datasets; and
determining a first parameter by providing the plurality of first datasets to a first function to perform a regression analysis, wherein
each of the plurality of first datasets includes a first processing result and a first processing condition, with the first processing result being obtained after a substrate processing apparatus executes a film process according to the first processing condition by supplying a processing liquid to an upper surface of a substrate on which a film is formed,
the first processing result includes a difference between film thicknesses obtained before and after execution of the film process at each of a plurality of different positions in a radial direction of the substrate, and
the first function that expresses, using the first processing condition and the first parameter, a difference between film thicknesses obtained before and after execution of the film process at any position in the radial direction of the substrate, is predetermined.

11. A processing condition determination method that is executed by an information processing apparatus managing a substrate processing apparatus,
the substrate processing apparatus executing a film process by supplying a processing liquid to an upper surface of a substrate on which a film is formed, wherein
the processing condition determination method includes determining a first processing condition for execution of the film process by the substrate processing apparatus,
the estimation algorithm is a first function for calculating a first processing result based on the first processing condition using a first parameter,
the first processing result includes a difference between film thicknesses obtained before and after execution of the film process at each of a plurality of different positions in a radial direction of the substrate,
the first parameter is obtained when a plurality of first datasets is provided to the first function and a regression analysis is performed,
each of the plurality of first datasets includes the first processing result and the first processing condition, with the first processing result being obtained after the substrate processing apparatus executes the film process according to the first processing condition, and
the determination of the processing condition includes, in a case in which a first processing result that is calculated based on a temporary first processing condition using the estimation algorithm satisfies an allowable condition, determining the temporary first processing condition as the first processing condition for driving the substrate processing apparatus.
